(19) United States
(12) Patent Application Publication
(10) Pub. No.: US 2026/0150400 A1
(43) Pub. Date: May 28, 2026

(54) SEMICONDUCTOR DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignees: Japan Display Inc., Tokyo (JP); IDEMITSU KOSAN CO., LTD., Tokyo (JP)

(21) Appl. No.: 19/387,691

(22) Filed: Nov. 13, 2025

(30) Foreign Application Priority Data
Nov. 22, 2024 (JP) 2024-203865

(51) Int. Cl. H10D 86/40; H10D 86/60

(52) U.S. Cl. CPC H10D 86/423; H10D 86/451; H10D 86/60

(57) ABSTRACT

A semiconductor device includes a first transistor and a second transistor. The first transistor includes a first oxide semiconductor layer, a first gate electrode layer over the first oxide semiconductor layer, and an insulating layer over the first gate electrode layer. The second transistor includes a second oxide semiconductor layer over the first semiconductor layer, a source electrode layer, and a drain electrode layer overlapping the source electrode layer with the second oxide semiconductor layer interposed therebetween. One of the source and drain electrode layers is provided as the same layer as the first oxide semiconductor layer. The other of the source and drain electrode layers is provided over the insulating layer. The insulating layer includes an opening portion in which the one of the source and drain electrode layers is exposed. The second oxide semiconductor layer is provided in the opening portion.

### CROSS-REFERENCE TO RELATED APPLICATION

This application claims the benefit of priority to Japanese Patent Application No. 2024-203865, filed on Nov. 22, 2024, the entire contents of which are incorporated herein by reference.

### FIELD

An embodiment of the present invention relates to a semiconductor device using an oxide semiconductor.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication Nos. 2021-141338, 2014-099601, 2021-153196, 2018-006730, 2016-184771, and 2021-108405). The transistor including an oxide semiconductor layer as a channel has a simple structure and can be manufactured by a low-temperature process, similar to a transistor including an amorphous silicon layer. Further, the transistor including an oxide semiconductor film is known to have a higher field effect mobility than the semiconductor device including an amorphous silicon film.

### SUMMARY

A semiconductor device according to an embodiment of the present invention includes a first transistor including a first oxide semiconductor layer and a second transistor including a second oxide semiconductor layer located over the first semiconductor layer. The first transistor further includes a first gate electrode layer over the first oxide semiconductor layer and an insulating layer over the first gate electrode layer. The second transistor further includes a source electrode layer and a drain electrode layer overlapping the source electrode layer with the second oxide semiconductor layer interposed therebetween. One of the source electrode layer and the drain electrode layer of the second transistor is provided as the same layer as the first oxide semiconductor layer of the first transistor. The other of the source electrode layer and the drain electrode layer of the second transistor is provided over the insulating layer. The insulating layer includes an opening portion in which the one of the source electrode layer and the drain electrode layer is exposed. The second oxide semiconductor layer is provided in the opening portion.

A semiconductor device according to an embodiment of the present invention includes a first transistor including a first oxide semiconductor layer and a second transistor including a second oxide semiconductor layer located over the first semiconductor layer. The first transistor further includes a first gate electrode layer over the first oxide semiconductor layer and an insulating layer over the first gate electrode layer. The second transistor further includes a source electrode layer and a drain electrode layer overlapping the source electrode layer with the second oxide semiconductor layer interposed therebetween. One of the source electrode layer and the drain electrode layer of the second transistor is a portion of the first oxide semiconductor layer of the first transistor. The other of the source electrode layer and the drain electrode layer of the second transistor is provided over the insulating layer. The second oxide semiconductor layer is in contact with the first oxide semiconductor layer.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a first transistor of a semiconductor device according to an embodiment of the present invention.

FIG. 3 is a schematic plan view showing a configuration of a second transistor of a semiconductor device according to an embodiment of the present invention.

FIG. 4 is a flowchart illustrating a method for manufacturing a semiconductor device according to an embodiment of the present invention.

FIG. 5 is a schematic cross-sectional view illustrating a method for manufacturing a semiconductor device according to an embodiment of the present invention.

FIG. 6 is a schematic cross-sectional view illustrating a method for manufacturing a semiconductor device according to an embodiment of the present invention.

FIG. 7 is a schematic cross-sectional view illustrating a method for manufacturing a semiconductor device according to an embodiment of the present invention.

FIG. 8 is a schematic cross-sectional view illustrating a method for manufacturing a semiconductor device according to an embodiment of the present invention.

FIG. 9 is a schematic cross-sectional view illustrating a method for manufacturing a semiconductor device according to an embodiment of the present invention.

FIG. 10 is a schematic cross-sectional view illustrating a method for manufacturing a semiconductor device according to an embodiment of the present invention.

FIG. 11 is a schematic cross-sectional view illustrating a method for manufacturing a semiconductor device according to an embodiment of the present invention.

FIG. 12 is a schematic cross-sectional view illustrating a method for manufacturing a semiconductor device according to an embodiment of the present invention.

FIG. 13 is a schematic cross-sectional view illustrating a method for manufacturing a semiconductor device according to an embodiment of the present invention.

FIG. 14 is a schematic cross-sectional view illustrating a method for manufacturing a semiconductor device according to an embodiment of the present invention.

FIG. 15 is a schematic cross-sectional view illustrating a method for manufacturing a semiconductor device according to an embodiment of the present invention.

FIG. 16 is a schematic cross-sectional view illustrating a method for manufacturing a semiconductor device according to an embodiment of the present invention.

FIG. 17 is a schematic cross-sectional view showing a configuration of a semiconductor device according to an embodiment of the present invention.

FIG. 18 is a schematic cross-sectional view showing a configuration of a semiconductor device according to an embodiment of the present invention.

FIG. 19 is a flowchart illustrating a method for manufacturing a semiconductor device according to an embodiment of the present invention.

FIG. 20 is a schematic cross-sectional view illustrating a method for manufacturing a semiconductor device according to an embodiment of the present invention.

FIG. 21 is a schematic cross-sectional view illustrating a method for manufacturing a semiconductor device according to an embodiment of the present invention.

FIG. 22 is a schematic cross-sectional view illustrating a method for manufacturing a semiconductor device according to an embodiment of the present invention.

FIG. 23 is a schematic cross-sectional view illustrating a method for manufacturing a semiconductor device according to an embodiment of the present invention.

FIG. 24 is a schematic cross-sectional view illustrating a method for manufacturing a semiconductor device according to an embodiment of the present invention.

FIG. 25 is a schematic cross-sectional view illustrating a method for manufacturing a semiconductor device according to an embodiment of the present invention.

FIG. 26 is a schematic cross-sectional view illustrating a method for manufacturing a semiconductor device according to an embodiment of the present invention.

FIG. 27 is a schematic cross-sectional view illustrating a method for manufacturing a semiconductor device according to an embodiment of the present invention.

FIG. 28 is a schematic cross-sectional view illustrating a method for manufacturing a semiconductor device according to an embodiment of the present invention.

FIG. 29 is a schematic cross-sectional view showing a configuration of a semiconductor device according to an embodiment of the present invention.

FIG. 30 is a flowchart illustrating a method for manufacturing a semiconductor device according to an embodiment of the present invention.

FIG. 31 is a schematic cross-sectional view illustrating a method for manufacturing a semiconductor device according to an embodiment of the present invention.

FIG. 32 is a schematic cross-sectional view illustrating a method for manufacturing a semiconductor device according to an embodiment of the present invention.

### DESCRIPTION OF EMBODIMENTS

Together with the miniaturization of semiconductor devices, there is a demand for high integration of transistors including an oxide semiconductor layer. A method of stacking transistors is known as a method for high integration of transistors. However, the transistors including the oxide semiconductor layer have a problem in that the characteristics of a lower transistor may vary due to the influence of the manufacturing process of an upper transistor.

An embodiment of the present invention can provide a semiconductor device that allows high integration of transistors including an oxide semiconductor layer.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a transistor” means a positional relationship in which the semiconductor device and the pixel electrode overlap in a plan view. In addition, a plan view refers to viewing from a direction perpendicular to a surface of the substrate.

In the specification and the like, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, in the embodiments, although a liquid crystal display device including a liquid crystal layer and an organic EL display device including an organic EL layer are described as examples of display devices, structures described in the embodiments can be applied to the other display device including the electro-optical layers described above.

In the specification and the like, the terms “film” and “layer” can be optionally interchanged with one another.

The functions of a source electrode and a drain electrode of a transistor may be interchanged depending on the voltage supplied to each electrode. Therefore, in the present specification and the like, the terms “source electrode layer” and “drain electrode layer” may be interchanged in some cases. Similarly, in the specification and the like, the terms “source region” and “drain region” may be interchanged in some cases.

In addition, the following embodiments can be combined with each other as long as there is no technical contradiction.

### First Embodiment

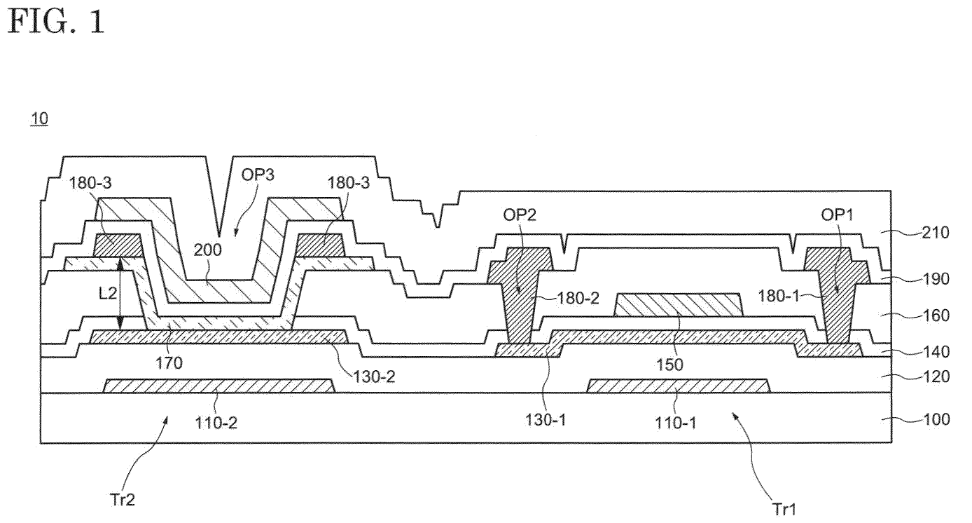

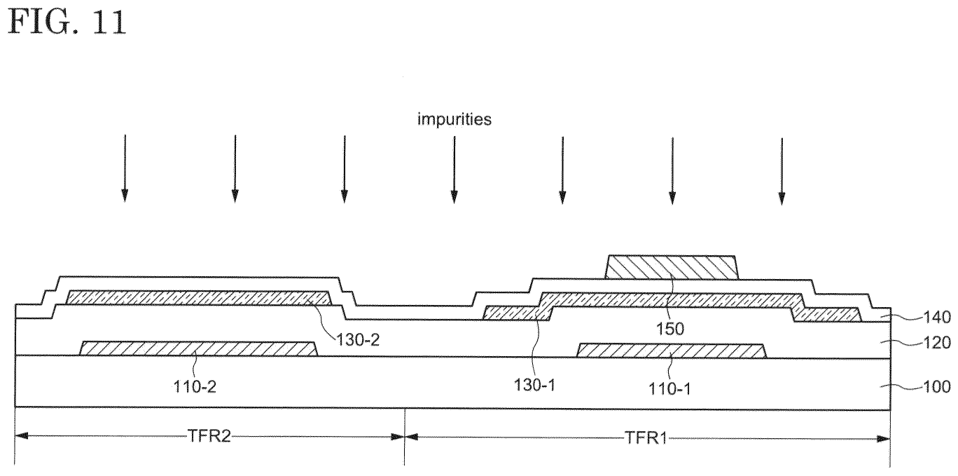

A semiconductor device 10 according to an embodiment of the present invention is described with reference to FIGS. 1 to 16.

### [1. Configuration of Semiconductor Device 10]

FIG. 1 is a schematic cross-sectional view showing a configuration of the semiconductor device 10 according to an embodiment of the present invention. As shown in FIG. 1, the semiconductor device 10 includes two transistors (a first transistor Tr1 and a second transistor Tr2) provided on a substrate 100. The structure of the second transistor Tr2 is different from the structure of the first transistor Tr1.

### [1-1. Configuration of First Transistor Tr1]

The first transistor Tr1 includes a light shielding layer 110-1, a first insulating layer 120, a first oxide semiconductor layer 130-1, a second insulating layer 140, a gate electrode layer 150, a third insulating layer 160, a source electrode layer 180-1, a drain electrode layer 180-2, a fourth insulating layer 190, and a fifth insulating layer 210. The light shielding layer 110-1 is provided on a substrate 100. The first insulating layer 120 is provided on the substrate 100 so as to cover the light shielding layer 110-1. The first oxide semiconductor layer 130-1 is provided on the first insulating layer 120. The second insulating layer 140 is provided on the first insulating layer 120 so as to cover the first oxide semiconductor layer 130-1. The gate electrode layer 150 is provided on the second insulating layer 140 so as to overlap the first oxide semiconductor layer 130-1. The third insulating layer 160 is provided on the second insulating layer 140 so as to cover the gate electrode layer 150. A first opening portion OP1 and a second opening portion OP2 are provided in the second insulating layer 140 and the third insulating layer 160. The first oxide semiconductor layer 130-1 is exposed through the first opening portion OP1 and the second opening portion OP2. The source electrode layer 180-1 is provided inside the first opening portion OP1 and on the third insulating layer 160. The drain electrode layer 180-2 is provided inside the second opening portion OP2 and on the third insulating layer 160. The fourth insulating layer 190 is provided on the third insulating layer 160 so as to cover the source electrode layer 180-1 and the drain electrode layer 180-2. The fifth insulating layer 210 is provided on the fourth insulating layer 190.

The source electrode layer 180-1 and the drain electrode layer 180-2 are in contact with the first oxide semiconductor layer 130-1 through the first opening portion OP1 and the second opening portion OP2, respectively. That is, the source electrode layer 180-1 and the drain electrode layer 180-2 are electrically connected to the first oxide semiconductor layer 130-1. The second insulating layer 140 is provided between the first oxide semiconductor layer 130-1 and the gate electrode layer 150. In the first transistor Tr1, a portion of the second insulating layer 140 functions as a gate insulating layer.

The gate electrode layer 150 is disposed on the first oxide semiconductor layer 130-1. Although the first transistor Tr1 is a so-called top-gate transistor, the first transistor Tr1 is not limited thereto. When the light shielding layer 110-1 is conductive, the light shielding layer 110-1 and the first insulating layer 120 can be used as a gate electrode layer and a gate insulating layer, respectively. In this case, the first transistor Tr1 is a so-called dual-gate transistor. In the dual-gate transistor, the light shielding layer 110-1 may be a floating electrode layer or may be electrically connected to the source electrode layer 180-1.

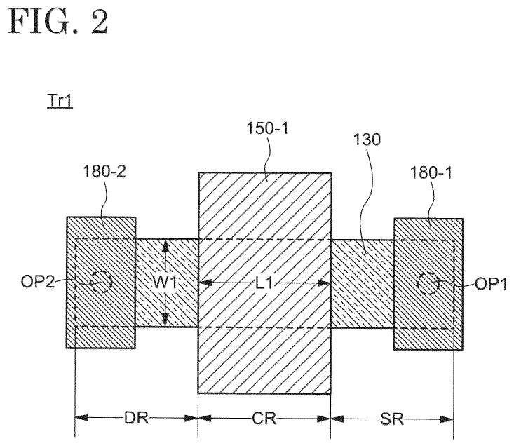

FIG. 2 is a schematic plan view showing a configuration of the first transistor Tr1 of the semiconductor device 10 according to an embodiment of the present invention. As shown in FIG. 2, the first oxide semiconductor layer 130-1 is divided into a source region SR, a drain region DR, and a channel region CR based on the gate electrode layer 150. The channel region CR is a region that overlaps the gate electrode layer 150, and the source region SR and the drain region DR are regions that do not overlap the gate electrode layer 150. An end portion of the channel region CR is substantially aligned with an end portion of the gate electrode layer 150. The source region SR and the drain region DR have higher electrical conductivities than the channel region CR. The source region SR and the drain region DR have conductive properties, and the channel region has semiconducting properties. The source electrode layer 180-1 and the drain electrode layer 180-2 are in contact with the source region SR and the drain region DR, respectively.

The first channel length L1 of the first transistor Tr1 corresponds to the distance between the source region SR and the drain region DR. The first channel width W1 of the first transistor Tr1 corresponds to the width in a direction perpendicular to a direction of the first channel length L1. In other words, the first channel length L1 and the first channel width W1 of the first transistor Tr1 correspond to the length and width, respectively, of the channel region CR.

### [1-2. Configuration of Second Transistor Tr2]

The second transistor Tr2 includes a light shielding layer 110-2, the first insulating layer 120, a source electrode layer 130-2, the second insulating layer 140, the third insulating layer 160, a second oxide semiconductor layer 170, a drain electrode layer 180-3, a fourth insulating layer 190, a gate electrode layer 200, and a fifth insulating layer 210. The light shielding layer 110-2 is provided on the substrate 100. The first insulating layer 120 is provided on the substrate so as to cover the light shielding layer 110-2. The source electrode layer 130-2 is provided on the first insulating layer 120. The second insulating layer 140 is provided on the first insulating layer 120 so as to cover the source electrode layer 130-2. The third insulating layer 160 is provided on the second insulating layer 140. A third opening portion OP3 is provided in the second insulating layer 140 and the third insulating layer 160. The source electrode layer 130-2 is exposed through the third opening portion OP3. The second oxide semiconductor layer 170 is provided inside the third opening portion OP3 and on the third insulating layer 160 so as to cover the bottom and side surfaces of the third opening portion OP3. The drain electrode layer 180-3 is provided on the second oxide semiconductor layer 170 without overlapping the third opening portion OP3. The fourth insulating layer 190 is provided inside the third opening portion OP3 and on the third insulating layer 160 so as to cover the second oxide semiconductor layer 170 and the drain electrode layer 180-3. The gate electrode layer 200 is provided inside the third opening portion OP3 and on the fourth insulating layer 190 so as to overlap the second oxide semiconductor layer 170. The fifth insulating layer 210 is provided on the fourth insulating layer 190 so as to cover the gate electrode layer 200.

The source electrode layer 130-2 is in contact with the second oxide semiconductor layer 170 below the second oxide semiconductor layer 170. The drain electrode layer 180-3 is in contact with the second oxide semiconductor layer 170 over the second oxide semiconductor layer 170. That is, the source electrode layer 130-2 and the drain electrode layer 180-3 are electrically connected to the second oxide semiconductor layer 170. The fourth insulating layer 190 is provided between the second oxide semiconductor layer 170 and the gate electrode layer 200. In the second transistor Tr2, a portion of the fourth insulating layer 190 functions as a gate insulating layer.

The source electrode layer 130-2 and the drain electrode layer 180-3 are disposed in a thickness direction of the second oxide semiconductor layer 170. The second transistor Tr2 is a so-called vertical transistor. In the second transistor Tr2, a channel is formed in a region provided on a side surface of the third opening portion OP3 in the second oxide semiconductor layer 170. Therefore, the second channel length L2 of the second transistor Tr2 substantially corresponds to the distance between the source electrode layer 130-2 and the drain electrode layer 180-3 in the thickness direction of the second oxide semiconductor layer 170 (see FIG. 1).

The second channel length L2 may be smaller than the first channel length L1. The second channel width W2 may be larger than the first channel width W1. In general, a vertical transistor can occupy a smaller area than a top-gate transistor or a bottom-gate transistor. Therefore, when the second transistor Tr2, which is a vertical transistor, is used as part of the transistors of the semiconductor device 10, the transistors of the semiconductor device 10 can be highly integrated.

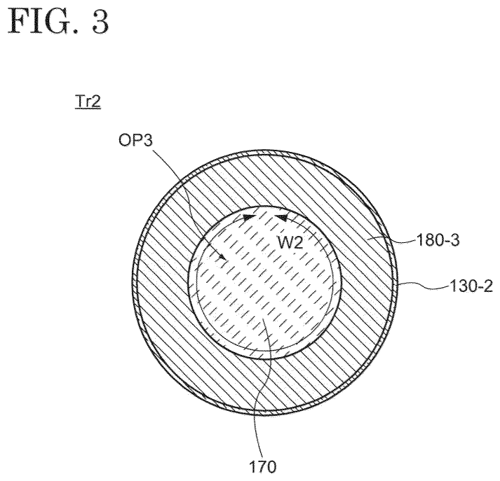

FIG. 3 is a schematic plan view showing a configuration of the second transistor Tr2 of the semiconductor device 10 according to an embodiment of the present invention. For convenience of explanation, the gate electrode layer 200 that overlaps the third opening portion OP3 over the drain electrode layer 180-3 is omitted from FIG. 3. As shown in FIG. 3, the second oxide semiconductor layer 170 is provided not only on the bottom surface of the third opening portion OP3 but also along the side surface of the third opening portion OP3. Therefore, the second channel width W2 of the second transistor Tr2 substantially corresponds to the inner periphery of the third opening portion OP3.

Although the planar shape of the opening portion OP3 is circular, the planar shape of the opening portion OP3 is not limited thereto. The planar shape of the third opening portion OP3 may be an ellipse or a polygon. Further, the second oxide semiconductor layer 170 may be provided on a portion of the side surface of the third opening portion OP3, rather than on the entire side surface of the third opening portion OP3.

### [1-3. Components of Semiconductor Device 10]

Some of the components are commonly provided in the first transistor Tr1 and the second transistor Tr2. Further, some of the components are formed by patterning one deposited film and are provided as the same layer. Details of each of components of the semiconductor device 10 are described below.

### [1-3-1. Substrate 100]

The substrate 100 is a support substrate of the first transistor Tr1 and the second substrate Tr2. For example, a rigid substrate having light transmitting properties, such as a glass substrate, a quartz substrate, or a sapphire substrate, can be used as the substrate 100. Further, a rigid substrate having no light-transmitting properties, such as a silicon substrate, can also be used as the substrate 100. Furthermore, a flexible substrate having light transmitting properties, such as a polyimide resin substrate, an acrylic resin substrate, a siloxane resin substrate, or a fluorine resin substrate, can also be used as the substrate 100. Impurities may be introduced into the flexible substrate in order to improve the heat resistance of the first substrate 100. In addition, the substrate 100 may be the above-described rigid or flexible substrate on which a silicon oxide film or a silicon nitride film is formed.

### [1-3-2. Light Shielding Layers 110-1 and 110-2]

The light shielding layers 110-1 and 110-2 are provided as the same layer. That is, the light shielding layers 110-1 and 110-2 are simultaneously formed by patterning one conductive film. The light shielding layers 110-1 and 110-2 can reflect or absorb external light. The light shielding layer 110-1 can prevent external light from entering the channel region CR of the first oxide semiconductor layer 130-1, and the light shielding layer 110-2 can prevent external light from entering the channel region of the second oxide semiconductor layer 170. Therefore, it is preferable that the light shielding layer 110-1 has an area larger than the channel region CR of the first oxide semiconductor layer 130-1 and the light shielding layer 110-2 has an area larger than the third opening portion OP3. A metal material can be used for the light shielding layers 110-1 and 110-2. For example, aluminum (Al), copper (Cu), titanium (Ti), molybdenum (Mo), tungsten (W), or an alloy thereof can be used for the light shielding layers 110-1 and 110-2. Specifically, although the alloy used for the light shielding layers 110-1 and 110-2 is molybdenum tungsten (MoW), the alloy is not limited thereto. Further, the thickness of the light shielding layers 110-1 and 110-2 is not limited to a certain value as long as it can prevent external light from entering.

### [1-3-3. First Insulating Layer 120]

The first insulating layer 120 can prevent impurities contained in the substrate 100 from diffusing into the first oxide semiconductor layer 130-1 and the second oxide semiconductor layer 170. In each of the first transistor Tr1 and the second transistor Tr2, the first insulating layer 120 is a base layer. An insulating oxide such as silicon oxide (SiOₓ) or silicon oxynitride (SiOₓN_{y}), or an insulating nitride such as silicon nitride (SiNₓ) or silicon nitride oxide (SiNₓO_{y}) can be used for the first insulating layer 120.

Here, silicon oxynitride (SiOₓN_{y}) is an oxide that contains a smaller proportion (x>y) of nitrogen (N) than oxygen (O). Further, silicon nitride oxide (SiNₓO_{y}) is a nitride that contains a smaller proportion (x>y) of oxygen than nitrogen.

The first insulating layer 120 may have a single layer structure or a stacked layer structure. In the first transistor Tr1, the first oxide semiconductor layer 130-1 is in contact with the first insulating layer 120. When the first oxide semiconductor layer 130-1 is in contact with an insulating nitride layer, oxygen in the first oxide semiconductor layer 130-1 is extracted, and oxygen deficiencies are likely to be generated in the first oxide semiconductor layer 130-1. Therefore, it is preferable that a layer in contact with the first oxide semiconductor layer 130-1 is an insulating oxide layer. For example, the first insulating layer 120 may have a stacked layer structure in which an insulating oxide layer is provided on an insulating nitride layer.

### [1-3-4. First Oxide Semiconductor Layer 130-1 and Source Electrode Layer 130-2]

The first oxide semiconductor layer 130-1 of the first transistor Tr1 and the source electrode layer 130-2 of the second transistor Tr2 are provided as the same layer. That is, the first oxide semiconductor layer 130-1 and the source electrode layer 130-2 are simultaneously formed by patterning one oxide semiconductor film. The first oxide semiconductor layer 130-1 and the source electrode layer 130-2 may have a single layer structure or a stacked layer structure. The first oxide semiconductor layer 130-1 and the source electrode layer 130-2 may be amorphous or crystalline. However, since the first transistor Tr1 including the first oxide semiconductor layer 130-1 is affected by the formation process of the second transistor Tr2, it is preferable that the first oxide semiconductor layer 130-1 and the source electrode layer 130-2 have thermally stable crystallinity. For example, the first oxide semiconductor layer 130-1 and the source electrode layer 130-2 preferably have a polycrystalline structure. The first oxide semiconductor layer 130-1 and the source electrode layer 130-2 having a polycrystalline structure can be formed by a polycrystalline oxide semiconductor (Poly-OS) technique. Therefore, hereinafter, the first oxide semiconductor layer 130-1 and the source electrode layer 130-2 may be referred to as a Poly-OS layer. Further, an oxide semiconductor included in the Poly-OS layer may be referred to as Poly-OS. Although details are described later, the Poly-OS layer can be formed by a sputtering method.

An oxide semiconductor containing two or more metal elements including indium (In) can be used for the Poly-OS layer. Gallium (Ga), zinc (Zn), aluminum (Al), hafnium (Hf), yttrium (Y), zirconium (Zr), and lanthanides can be used as metal elements other than indium. It is preferable to use an oxide semiconductor in which the ratio of indium to all metal elements is greater than or equal to 50% in an atomic ratio. When the ratio of the indium is increased, the Poly-OS layer is easily crystallized. Further, it is preferable that gallium is included in the metal elements other than indium. Gallium belongs to the same Group 13 elements as indium. Therefore, the crystallinity of the oxide semiconductor layer 140 is hardly inhibited by gallium.

The composition of the Poly-OS layer formed by a sputtering method depends on the composition of a sputtering target. That is, the composition of the oxide semiconductor layer 140 is approximately the same as that of the sputtering target. Therefore, the composition of the metal elements of the oxide semiconductor layer 140 can be specified based on the composition of the metal elements of the sputtering target. The composition of the oxide semiconductor layer 140 may be specified by an XRD method. Specifically, the composition of the metal elements of the Poly-OS layer can be specified based on the crystal structure and lattice constant of the Poly-OS layer obtained by the XRD method. Further, the composition of the metal elements of the Poly-OS layer can also be specified using X-ray fluorescence analysis or Electron Probe Micro Analyzer (EPMA) analysis. In addition, oxygen contained in the Poly-OS layer is not limited thereto because oxygen changes depending on the process conditions of a sputtering method and the like.

As described above, the first oxide semiconductor layer 130-1 includes the channel region CR having semiconductor properties and the source region SR and drain region DR having conductive properties. Thus, the conductivity of the Poly-OS layer can be changed while having the same polycrystalline structure. The Poly-OS layer has semiconductor properties when the amount of oxygen deficiencies is small, and has conductive properties when the amount of oxygen deficiencies is large. Therefore, the properties of the Poly-OS layer can be controlled by adjusting the amount of oxygen deficiencies in the Poly-OS layer. When the amount of oxygen deficiencies in the Poly-OS layer is increased, the source electrode layer 130-2 has conductive properties, similar to the source region SR and drain region DR.

The thickness of the first oxide semiconductor layer 130-1 and the source electrode layer 130-2 is greater than or equal to 10 nm and less than or equal to 100 nm, preferably greater than or equal to 15 nm and less than or equal to 70 nm, and more preferably greater than or equal to 15 nm and less than or equal to 40 nm.

### [1-3-5. Second Insulating Layer 140]

The second insulating layer 140 forms a side surface of the third opening portion OP3 in the second transistor Tr2, and a portion of the second insulating layer 140 is in contact with the first oxide semiconductor layer 130-1 and functions as a gate insulating layer in the first transistor Tr1. Therefore, an insulating oxide can be used for the second insulating layer 140. The second insulating layer 140 that functions as a gate electrode layer preferably has few defects and a composition close to the stoichiometric ratio. Specifically, it is preferable that no defects are observed in the second insulating layer 140 when evaluated by an electron spin resonance (ESR) method.

Although the thickness of the second insulating layer 140 is not limited to a certain value, the thickness is greater than or equal to 50 nm and less than or equal to 300 nm, preferably greater than or equal to 60 nm and less than or equal to 200 nm, and more preferably greater than or equal to 70 nm and less than or equal to 150 nm.

### [1-3-6. Gate Electrode Layer 150]

The gate electrode layer 150 overlaps the first oxide semiconductor layer 130-1 with the second insulating layer 140 interposed therebetween. The same metal material as the light shielding layer 110 can be used for the gate electrode layer 150.

### [1-3-7. Third Insulating Layer 160]

Although the third insulating layer 160 is an interlayer insulating layer in the first transistor Tr1, the third insulating layer 160 forms the side surface of the third opening portion OP3 in the second transistor Tr2. An insulating oxide or an insulating nitride similar to the first insulating layer 120 can be used for the third insulating layer 160. The third insulating layer 160 may have a single layer structure or a stacked structure. For example, the third insulating layer 160 may have a stacked structure in which an insulating oxide layer is provided on an insulating nitride layer. In this case, since the second oxide semiconductor layer 170 is in contact with the insulating nitride layer, it is preferable that the thickness of the insulating nitride layer is smaller than the thickness of the insulating oxide layer.

### [1-3-8. Second Oxide Semiconductor Layer 170]

The second oxide semiconductor layer 170 may have a single layer structure or a stacked layer structure. The second oxide semiconductor layer 170 may have an amorphous structure, a microcrystalline structure, or a polycrystalline structure. The same oxide semiconductor as the first oxide semiconductor layer 130-1 may be used for the second oxide semiconductor layer 170, or an oxide semiconductor different from that of the first oxide semiconductor layer 130-1 may be used for the second oxide semiconductor layer 170. For example, an oxide containing indium, gallium, and zinc (IGZO) can be used for the second oxide semiconductor layer 170.

The thickness of the second oxide semiconductor layer 170 is greater than or equal to 10 nm and less than or equal to 150 nm, preferably greater than or equal to 10 nm and less than or equal to 100 nm, and more preferably greater than or equal to 10 nm and less than or equal to 50 nm.

### [1-3-9. Source Electrode Layer 180-1, Drain Electrode Layer 180-2, and Drain Electrode Layer 180-3]

The source electrode layer 180-1 and the drain electrode layer 180-2 of the first transistor Tr1 and the drain electrode layer 180-3 of the second transistor Tr2 are provided as the same layer. That is, the source electrode layer 180-1, the drain electrode layer 180-2, and the drain electrode layer 180-3 are simultaneously formed by patterning one conductive film. The same metal material as the light shielding layer 110-1 can be used for the source electrode layer 180-1, the drain electrode layer 180-2, and the drain electrode layer 180-3.

### [1-3-10. Fourth Insulating Layer 190]

Although the fourth insulating layer 190 is a protective layer in the first transistor Tr1, a portion of the fourth insulating layer 190 is in contact with the second oxide semiconductor layer 170 and functions as a gate insulating layer in the second transistor Tr2. Therefore, an insulating oxide can be used for the fourth insulating layer 190. The fourth insulating layer 190 that functions as a gate insulating layer preferably has few defects and a composition close to the stoichiometric ratio. Specifically, it is preferable that no defects are observed in the fourth insulating layer 190 when evaluated by an ESR method.

Although the thickness of the fourth insulating layer 190 is not limited to a certain value, the thickness is greater than or equal to 50 nm and less than or equal to 300 nm, preferably greater than or equal to 60 nm and less than or equal to 200 nm, and more preferably greater than or equal to 70 nm and less than or equal to 150 nm.

### [1-3-11. Gate Electrode Layer 200]

On the bottom and side surfaces of the third opening portion OP3, the gate electrode layer 200 overlaps the second oxide semiconductor layer 170 with the fourth insulating layer 190 interposed therebetween. The gate electrode layer 200 may be provided so as to fill the third opening portion OP3. The same metal material as the light shielding layer 110-1 can be used for the gate electrode layer 200.

### [1-3-12. Fifth Insulating Layer 210]

The fifth insulating layer 210 is a protective layer. Similar to the first insulating layer 120, an insulating nitride or an insulating oxide can be used for the fifth insulating layer 210. The fifth insulating layer 210 may have a single layer structure or a stacked layer structure. For example, the fifth insulating layer 210 may have a stacked layer structure in which an insulating oxide layer is provided on an insulating nitride layer.

### [2. Manufacturing Method of Semiconductor Device 10]

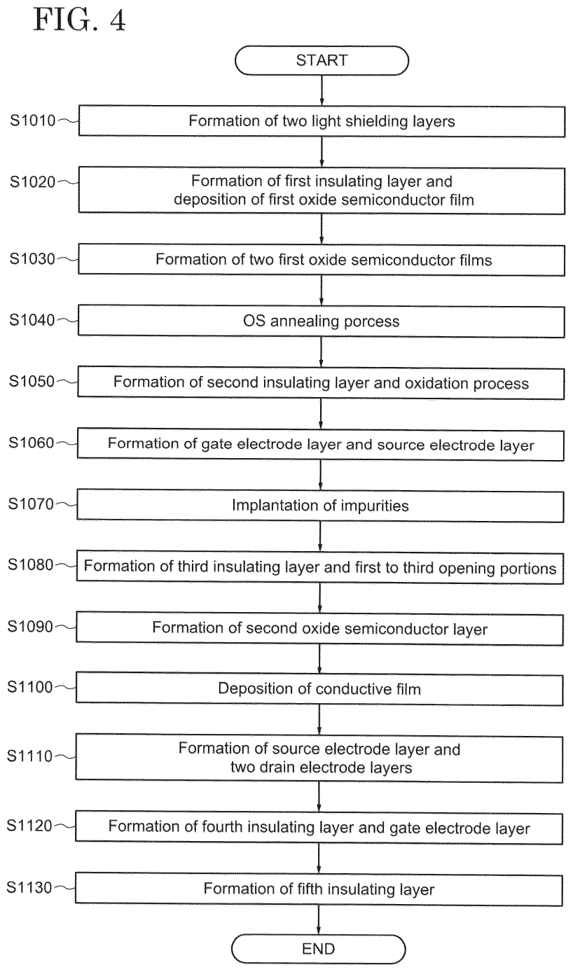

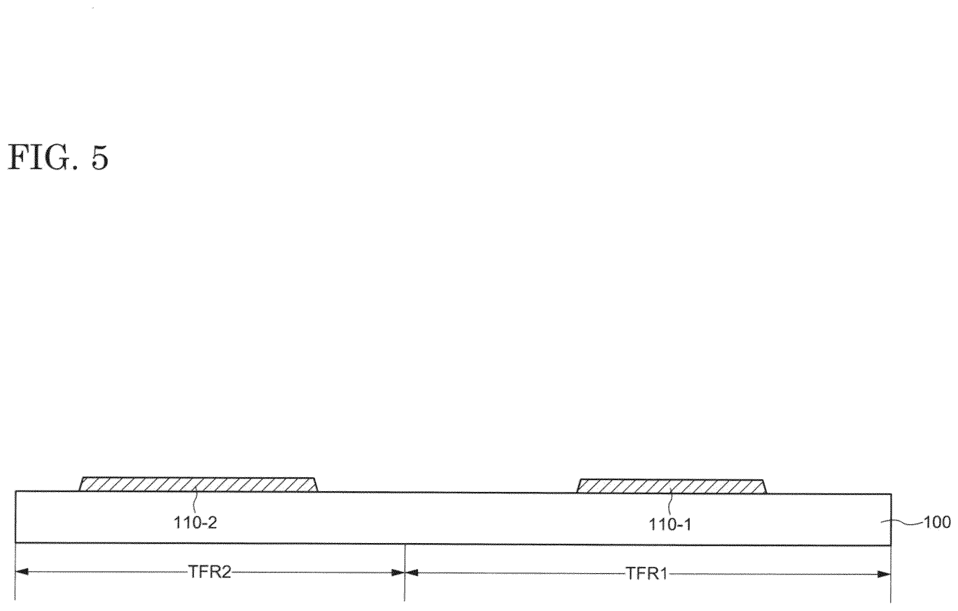

FIG. 4 is a flowchart illustrating a method for manufacturing the semiconductor device 10 according to an embodiment of the present invention. FIGS. 5 to 14 are schematic cross-sectional views illustrating a method for manufacturing the semiconductor device 10 according to an embodiment of the present invention. Although the method for manufacturing the semiconductor device 10 in which the first oxide semiconductor layer 130-1 and the source electrode layer 130-2 contain the Poly-OS is described below as an example, the method for manufacturing the semiconductor device 10 is not limited thereto.

As shown in FIG. 4, the method for manufacturing the semiconductor device 10 includes steps S1010 to S1130. Although steps S1010 to S1130 are described below in this order, the order of the steps may be reversed in the method for manufacturing the semiconductor device 10. The method for manufacturing the semiconductor device 10 may also include additional steps. Hereinafter, for convenience of explanation, the region where the first transistor Tr1 is formed is described as a first transistor formation region TFR1, and the region where the second transistor Tr2 is formed is described as a second transistor formation region TFR2.

In step S1010, the light shielding layer 110-1 having a predetermined pattern shape is formed on the substrate 100 in the first transistor formation region TFR1, and the light shielding layer 110-2 having a predetermined pattern shape is formed on the substrate 110 in the second transistor formation region TFR2 (see FIG. 5). The light shielding layers 110-1 and 110-2 are patterned by a photolithography method.

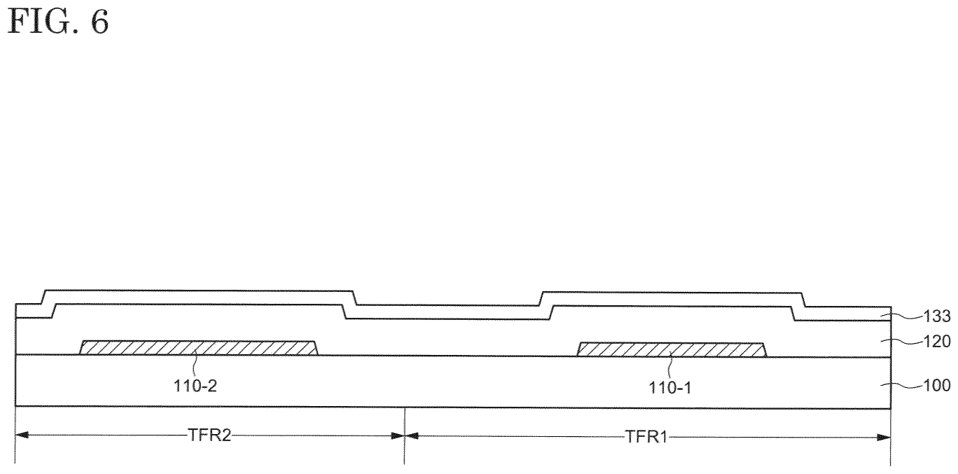

In step S1020, the first insulating layer 120 is formed to cover the light shielding layers 110-1 and 110-2, and then a first oxide semiconductor film 133 is deposited on the first insulating layer 120 (see FIG. 6). The first insulating layer 120 is deposited by a chemical vapor deposition (CVD) method. On the other hand, the first oxide semiconductor film 133 is deposited by a sputtering method. The first oxide semiconductor film 133 deposited by a sputtering method has an amorphous structure. In the Poly-OS technology, it is preferable that the first oxide semiconductor film 133 has an amorphous structure after film formation and before a heat treatment so that the Poly-OS layer has a uniform polycrystalline structure within the substrate plane. In other words, the first oxide semiconductor film 133 is preferably deposited under conditions that minimize crystallization of the first oxide semiconductor film 133 immediately after deposition. When the first oxide semiconductor film 133 is deposited by a sputtering method, the first oxide semiconductor film 133 is deposited while controlling the temperature of the object to be formed (the substrate 100 and the layer formed on the substrate 100) at the temperature lower than or equal to 100° C., preferably lower than or equal to 80° C., and more preferably lower than or equal to 50° C. The first oxide semiconductor film 133 is deposited under conditions of a low oxygen partial pressure. For example, the oxygen partial pressure is greater than or equal to 2% and less than or equal to 20%, preferably greater than or equal to 3% and less than or equal to 15%, and more preferably greater than or equal to 3% and less than 10%.

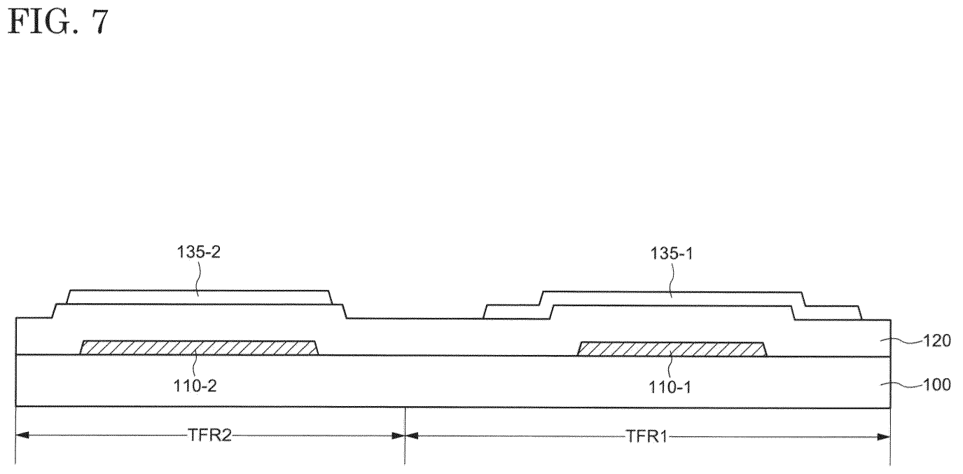

In step S1030, a first oxide semiconductor film 135-1 having a predetermined pattern shape is formed in the first transistor formation region TFR1 and a second oxide semiconductor film 135-2 having a predetermined shape is formed in the second transistor formation region TFR2 by a photolithography method (see FIG. 7). The first oxide semiconductor film 133 having an amorphous structure can be easily patterned by a photolithography method. The first oxide semiconductor film 133 may be etched by wet etching or dry etching. In wet etching, the first oxide semiconductor film 135 can be etched using an acidic etching solution. For example, oxalic acid, PAN, sulfuric acid, a hydrogen peroxide solution, or hydrofluoric acid can be used as the etching solution.

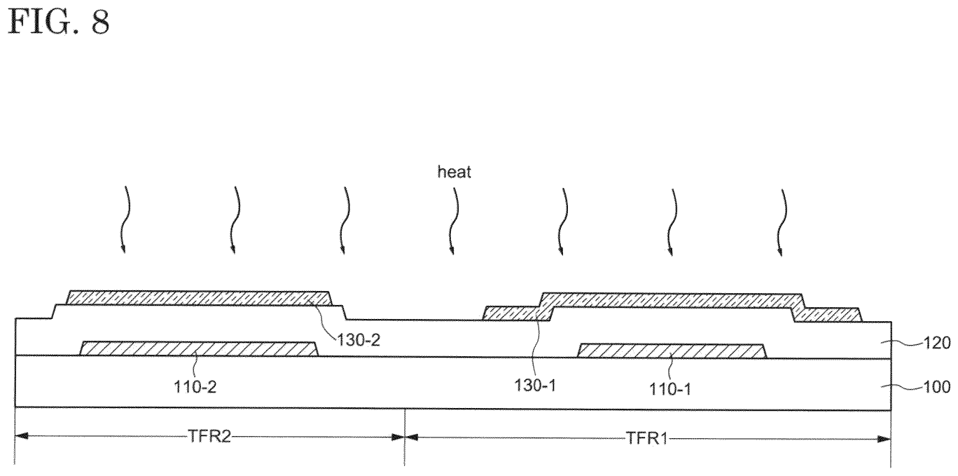

In step S1040, a heat treatment is performed on the first-1 oxide semiconductor film 135-1 and the first-2 oxide semiconductor film 135-2 having a predetermined pattern shape (see FIG. 8). Hereinafter, the heat treatment performed in step S1030 is referred to as “OS annealing process.” In the OS annealing process, the first oxide semiconductor film 135-1 and the first oxide semiconductor film 135-2 are held at a predetermined reaching temperature for a predetermined time. The predetermined reaching temperature is higher than or equal to 300° C. and lower than or equal to 500° C., preferably higher than or equal to 350° C. and less than or equal to 450° C. The holding time at the reaching temperature is greater than or equal to 15 minutes and less than or equal to 120, and preferably greater than or equal to 30 minutes and less than or equal to 60 minutes. When the first-1 oxide semiconductor film 135-1 and the first-2 oxide semiconductor film 135-2 are crystallized by the OS annealing process, each of the first oxide semiconductor layer 130-1 (i.e., the first oxide semiconductor layer 130-1 including the Poly-OS) and the source electrode layer 130-2 (i.e., the source electrode layer 130-2 including the Poly-OS) has a polycrystalline structure. The Poly-OS layer has excellent etching resistance. In other words, the Poly-OS layer has an extremely low etching rate when etching using an etching solution or etching gas. Specifically, the Poly-OS layer is not etched even by the etching solution used when etching the first oxide semiconductor film 133. Such excellent etching resistance of the Poly-OS layer is a characteristic that cannot be obtained by a conventional oxide semiconductor layer having a polycrystalline structure that is manufactured by a process at a temperature lower than 500° C. Further, the Poly-OS layer has high crystallinity and is less susceptible to heat load than an oxide semiconductor layer having an amorphous structure or a conventional oxide semiconductor layer having a polycrystalline structure.

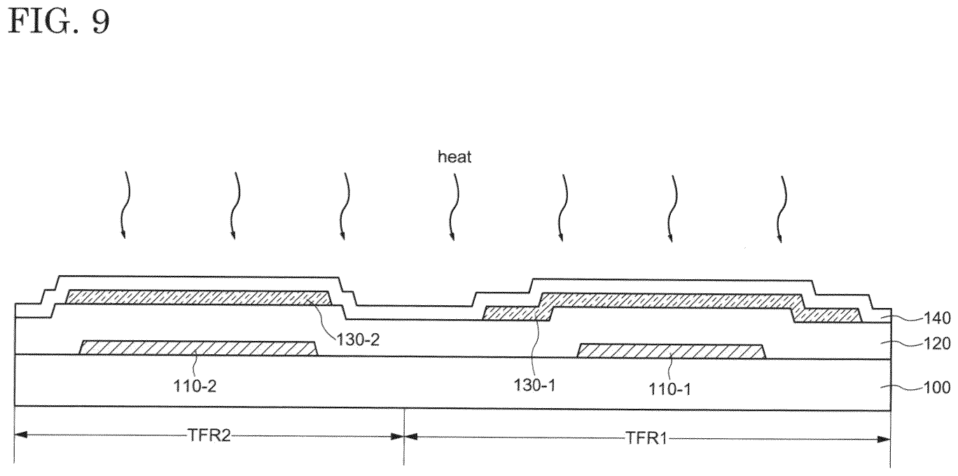

In step S1050, the second insulating layer 140 is formed to cover the first oxide semiconductor layer 130-1 and the source electrode layer 130-2, and then a heat treatment is performed on the first oxide semiconductor layer 130-1 and the source electrode layer 130-2 (see FIG. 9). Hereinafter, the heat treatment performed in step S1040 is referred to as “oxidation annealing process.” The second insulating layer 140 is deposited by a CVD method. The formation of the first-1 oxide semiconductor film 135-1 and the first-2 oxide semiconductor layer 135-2 (i.e., patterning of the first oxide semiconductor film 133) and the formation of the second insulating layer 140 on the first oxide semiconductor layer 130-1 and the source electrode layer 130-2 generate many oxygen deficiencies in the first oxide semiconductor layer 130-1 and the source electrode layer 130-2. When the oxidation annealing process is performed, oxygen is supplied from the second insulating layer 140 to the first oxide semiconductor layer 130-1 and the source electrode layer 130-2, and the oxygen deficiencies in the first oxide semiconductor layer 130-1 and the source electrode layer 130-2 are repaired. In addition, a process of introducing oxygen into the second insulating layer 140 may be performed after the second insulating layer 140 is formed. In this case, since the amount of oxygen in the second insulating layer 140 increases, sufficient oxygen can be supplied to the first oxide semiconductor layer 130-1 and the source electrode layer 130-2 by the oxidation annealing process.

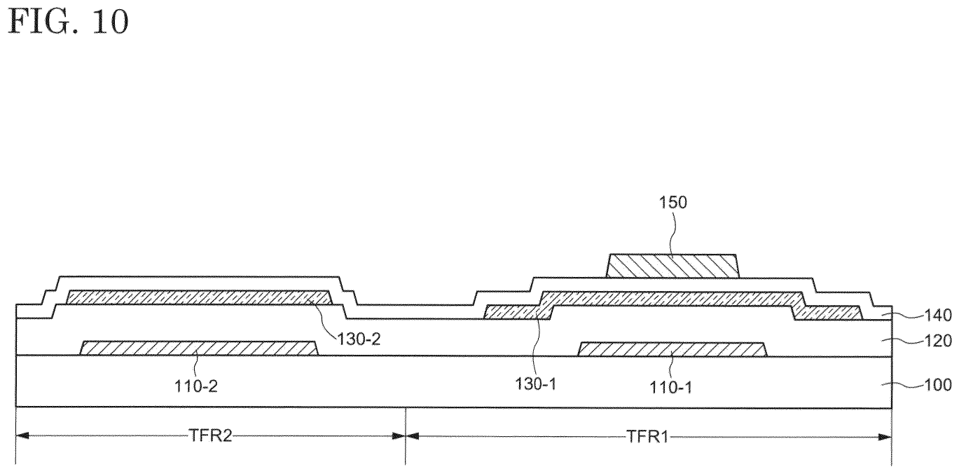

In step S1060, the gate electrode layer 150 is formed on the second insulating layer 140 in the first transistor formation region TFR1 (see FIG. 10). The gate electrode layer 150 is deposited by a sputtering method, and the gate electrode layer 150 is patterned by a photolithography method.

In step S1070, impurities are implanted into the first oxide semiconductor layer 130-1 and the source electrode layer 130-2 through the second insulating layer 140. For example, the impurities can be implanted into the first oxide semiconductor layer 130-1 and the source electrode layer 130-2 by an ion implantation method. For example, argon (Ar), phosphorus (P), or boron (B) can be used as the impurity. When the gate electrode layer 150-1 is formed on the first oxide semiconductor layer 130-1, the gate electrode layer 150-1 acts as a mask, therefore, preventing the impurities from being implanted into the first oxide semiconductor layer 130-1. As a result, since the impurities are not implanted into a region of the first oxide semiconductor layer 130-1 that overlaps the gate electrode layer 150-1, the channel region CR is formed in this region. Meanwhile, the source region SR and the drain region DR are formed in regions of the first oxide semiconductor layer 130-1 into which the impurities are implanted. In the source region SR, the drain region DR, and the source electrode layer 130-2, oxygen deficiencies are generated by the implantation of impurities, and hydrogen is trapped in the oxygen deficiencies. As a result, the source region SR, the drain region DR, and the source electrode layer 130-2 are conductive and have higher electrical conductivity than the channel region CR.

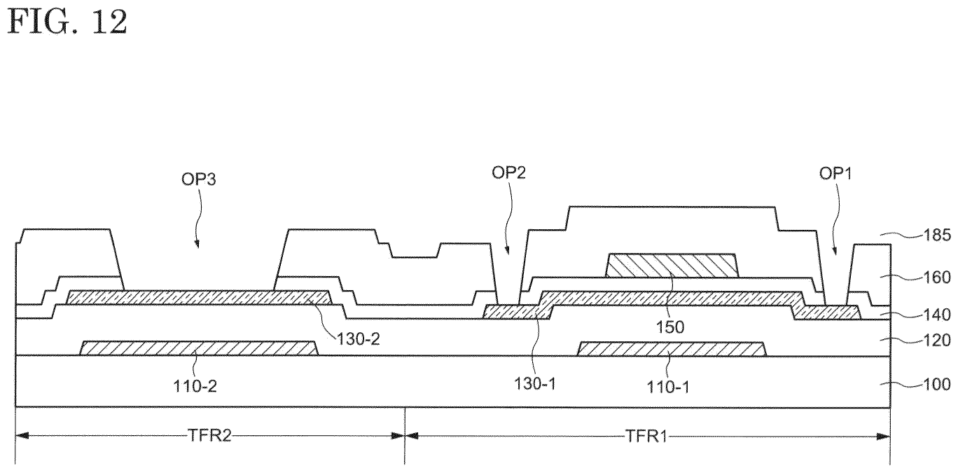

In step S1080, the third insulating layer 160 is formed to cover the gate electrode layer 150 and the source electrode layer 130-2, and then the first opening portion OP1 and the second opening portion OP2 are formed in the first transistor formation region TFR1 so as to expose the first oxide semiconductor layer 130-1, and the third opening OP3 is formed in the second transistor formation region TFR2 so as to expose the source electrode layer 130-2 (see FIG. 12). The source region SR is exposed through the first opening portion OP1, and the drain region DR is exposed through the second opening portion OP2.

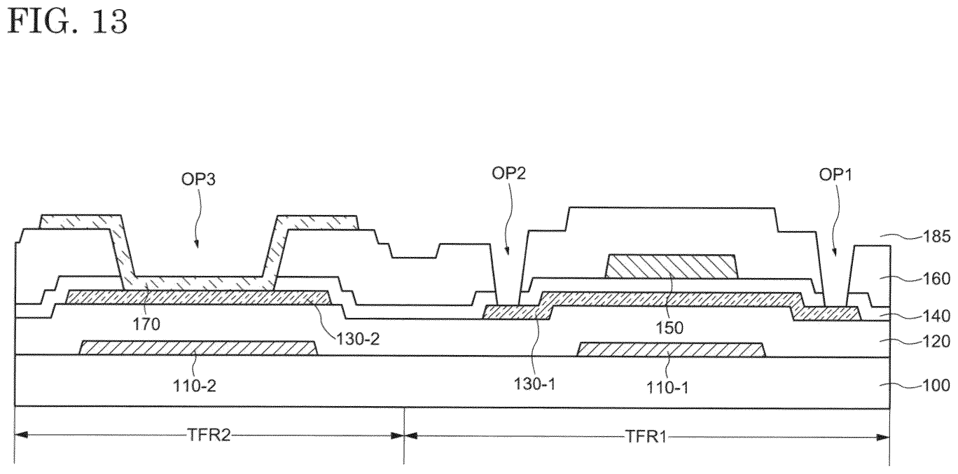

In step S1090, the second oxide semiconductor layer 170 having a predetermined pattern shape is formed in the second transistor formation region TFR2 so as to cover the bottom surface (i.e., the exposed source electrode layer 150-2) and side surfaces of the third opening portion OP3 (see FIG. 13). The second oxide semiconductor layer 170 is deposited by a sputtering method, and is patterned by a photolithography method. The second oxide semiconductor layer 170 immediately after formation is in contact with the first oxide semiconductor layer 130 at the bottom surfaces of the first opening portion OP1 and the second opening portion OP2. In this case, when the first oxide semiconductor layer includes a conventional oxide semiconductor having a polycrystalline structure, the first oxide semiconductor layer is also etched by an etching solution or etching gas used in etching the second oxide semiconductor layer 170. Meanwhile, the Poly-OS layer has excellent etching resistance. Therefore, the first oxide semiconductor layer 130-1 exposed through the first opening OP1 and the second opening OP2 is hardly etched even when the second oxide semiconductor layer 170 is etched.

In addition, a heat treatment (so-called OS annealing process) may be performed on the second oxide semiconductor layer 170 having a predetermined pattern shape. By the OS annealing process, the second oxide semiconductor layer 170 having a polycrystalline structure can also be formed.

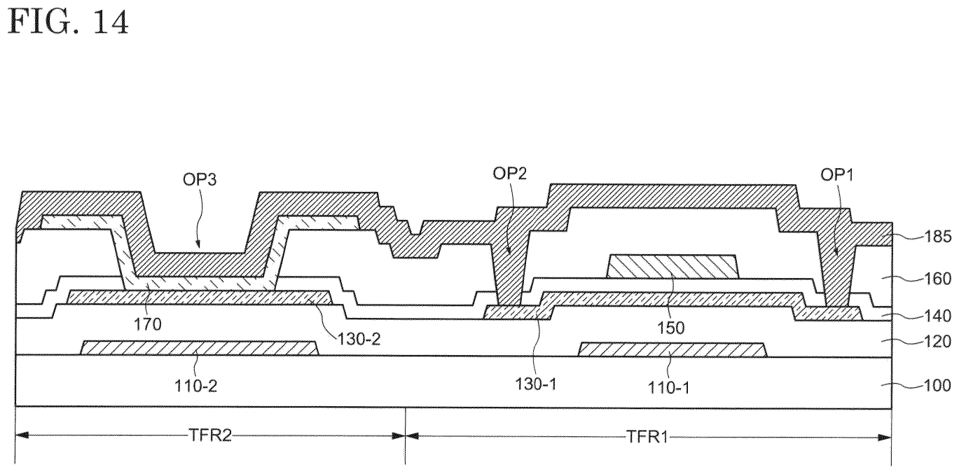

In step S1100, a conductive film 185 is deposited on the third insulating layer 160 so as to cover the second oxide semiconductor layer 170 having a predetermined pattern shape (see FIG. 14). The conductive film 185 is deposited by a sputtering method.

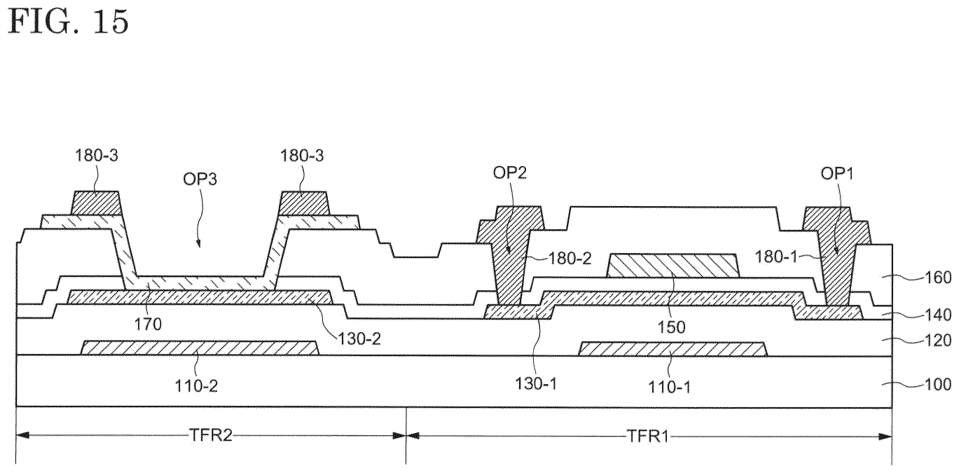

In step S1110, the conductive film 185 is patterned to form the source electrode layer 180-1 and the drain electrode layer 180-2 having a predetermined pattern shape in the first transistor formation region TFR1, and the drain electrode layer 180-3 having a predetermined pattern shape in the second transistor formation region TFR2 (see FIG. 15). That is, the source electrode layer 180-1 and the drain electrode layer 180-2 in the first transistor formation region TFR1 and the drain electrode layer 180-3 in the second transistor formation region TFR2 are the same layer formed from the conductive film 185. The conductive film 185 is patterned by a photolithography method.

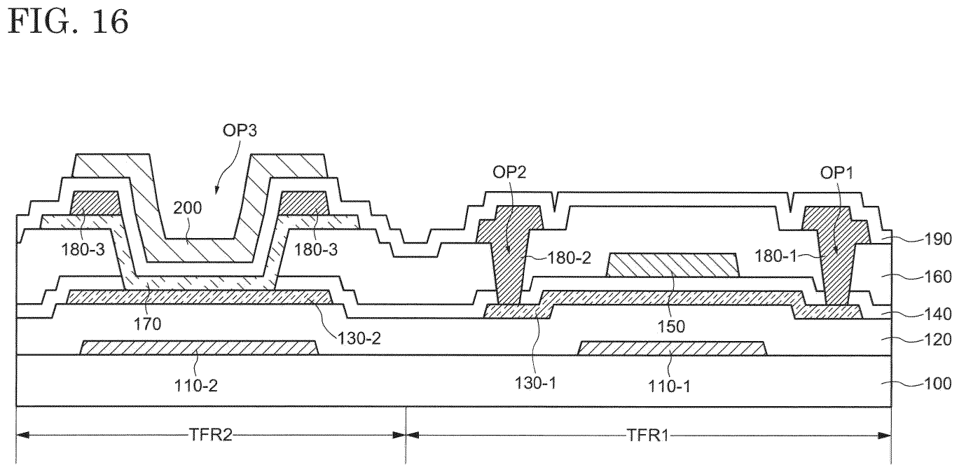

In step S1120, the fourth insulating layer 190 is formed on the third insulating layer 160 so as to cover the source electrode layer 180-1 and the drain electrode layer 180-2 in the first transistor formation region TFR1 and the drain electrode layer 180-3 and the second oxide semiconductor layer 170 in the second transistor formation region TFR2. Then, the gate electrode layer 200 having a predetermined pattern shape is formed on the fourth insulating layer 190 in the second transistor formation region TFR2 (see FIG. 16). The fourth insulating layer 190 is deposited by a CVD method. The gate electrode layer 200 is deposited by a sputtering method, and the gate electrode layer 200 is patterned by a photolithography method. The gate electrode layer 200 is patterned on the bottom and side surfaces of the third opening portion OP3 so as to have a pattern shape that overlaps the second oxide semiconductor layer 170 with the fourth insulating layer 190 interposed therebetween.

In addition, a heat treatment (so-called oxidation annealing process) may be performed on the second oxide semiconductor layer 170 after the formation of the fourth insulating layer 190 and before the formation of the gate electrode layer 200. By the oxidation annealing process, oxygen deficiencies in the second oxide semiconductor layer 170 can be repaired.

In step S1130, the fifth insulating layer 210 is formed on the fourth insulating layer 190 so as to cover the gate electrode layer 200 having a predetermined pattern shape. In this way, the semiconductor device 10 shown in FIG. 1 is manufactured.

The semiconductor device 10 according to the present embodiment includes the first transistor Tr1 including the first oxide semiconductor layer 130-1 and the second transistor Tr2 including the second oxide semiconductor layer 170 formed over the first oxide semiconductor layer 130-1. The first transistor Tr1 and the second transistor Tr2 have some of their components in common, and the second transistor Tr2 is formed over the first transistor Tr1. The first oxide semiconductor layer 130-1 preferably has thermally stable crystallinity. For example, the first oxide semiconductor layer 130-1 containing the Poly-OS has excellent etching resistance and is less susceptible to thermal load. Therefore, even when the second transistor Tr2 is formed after the first oxide semiconductor layer 130-1 of the first transistor Tr1 is formed, the first transistor Tr1 is hardly affected by the formation process of the second transistor Tr2, thereby suppressing fluctuations in the characteristics of the first transistor Tr1. Further, since the second transistor Tr2 is a vertical transistor, the area occupied by the second transistor Tr2 can be further reduced. Therefore, high integration of transistors can be achieved in the semiconductor device 10.

### Modification

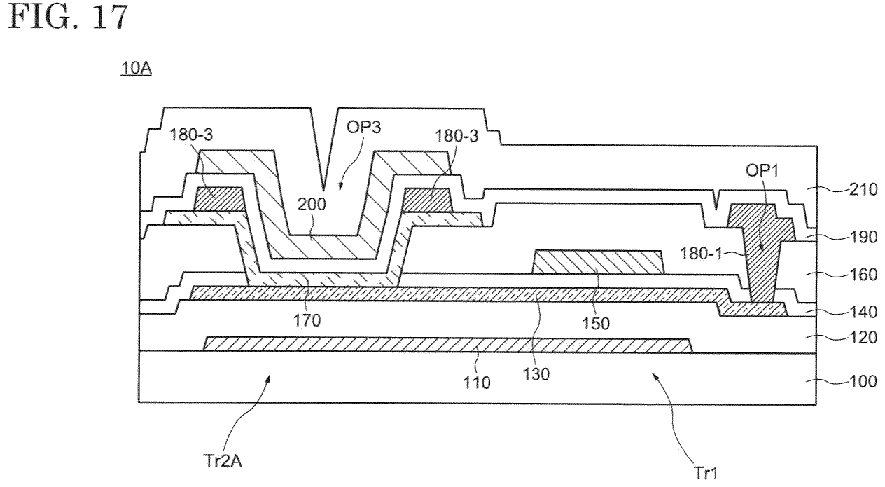

A semiconductor device 10A, which is a modification of the semiconductor device 10 according to an embodiment of the present invention, is described with reference to FIG. 17. In addition, when a configuration of the semiconductor device 10A is similar to that of the semiconductor device 10, the description of the configuration of the semiconductor device 10A may be omitted. In the present modification, the light shielding layer 110-1 and the first oxide semiconductor layer 130-1 are referred to as the light shielding layer 110 and the first oxide semiconductor layer 130, respectively, for convenience of explanation

FIG. 17 is a schematic cross-sectional view showing a configuration of the semiconductor device 10A according to an embodiment of the present invention. As shown in FIG. 17, the semiconductor device 10A includes two transistors (a first transistor Tr1 and a second transistor Tr2) provided over the substrate 100. The structure of the second transistor Tr2A is different from the structure of the first transistor Tr1.

The second transistor Tr2A includes the light shielding layer 110, the first insulating layer 120, the first oxide semiconductor layer 130, the second insulating layer 140, the third insulating layer 160, the second oxide semiconductor layer 170, the drain electrode layer 180-3, the fourth insulating layer 190, the gate electrode layer 200, and the fifth insulating layer 210. The light shielding layer 110 is provided in common with the first transistor Tr1 and the second transistor Tr2. The second oxide semiconductor layer 170 is provided inside the third opening OP3 and on the third insulating layer 160 so as to cover the bottom and side surfaces of the third opening OP3. At the bottom of the third opening OP3, the second oxide semiconductor layer 170 is in direct contact with a region of the first oxide semiconductor layer 130 that does not overlap the gate electrode layer 150, i.e., the drain region DR. In other words, the drain region DR of the first oxide semiconductor layer 130 functions as a source electrode layer in the second transistor Tr2A.

In the semiconductor device 10A according to the present modification, the second oxide semiconductor layer 170 over the first oxide semiconductor layer 130 is in direct contact with the drain region of the first oxide semiconductor layer 130. As a result, since the second transistor Tr2A overlaps the first transistor Tr1, the area occupied by the second transistor Tr2A is further reduced. Therefore, high integration of transistors can be achieved in the semiconductor device 10A.

### Second Embodiment

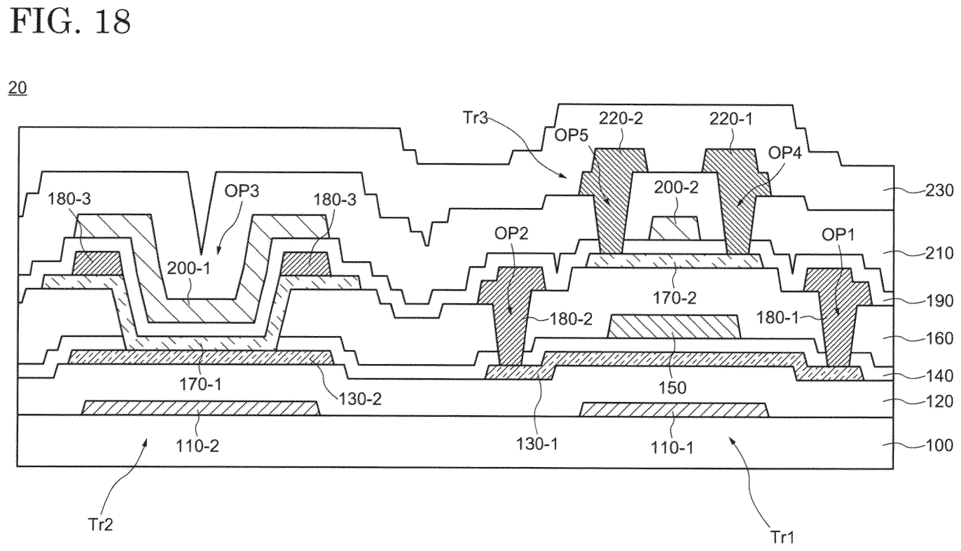

A semiconductor device 20 according to an embodiment of the present invention is described in reference with FIGS. 18 to 28. In addition, when a configuration of the semiconductor device 20 is similar to the configuration of the semiconductor device 10, the description of the configuration of the semiconductor device 20 may be omitted.

### [1. Configuration of Semiconductor Device 20]

FIG. 18 is a schematic cross-sectional view showing a configuration of the semiconductor device 20 according to an embodiment of the present invention. As shown in FIG. 18, the semiconductor device 20 includes three transistors (a first transistor Tr1, a second transistor Tr2, and a third transistor Tr3) provided on the substrate 100. The structure of the third transistor Tr3 is different from the structures of the first transistor Tr1 and the second transistor Tr2.

Here, since a configuration of the first transistor Tr1 according to the present embodiment is similar to the configuration of the first transistor Tr1 described in the First Embodiment, description thereof is omitted. Further, since a configuration of the second transistor Tr2 according to the preset embodiment is similar to the configuration of the second transistor Tr2 described in the First Embodiment, description thereof is omitted. However, for convenience of explanation, the second oxide semiconductor layer 170 and the gate electrode layer 200 of the First Embodiment are described as a second oxide semiconductor layer 170-1 and a gate electrode layer 200-1, respectively, in the present embodiment.

### [1-1. Configuration of Third Transistor Tr3]

The third transistor Tr3 includes the third insulating layer 160, a third oxide semiconductor layer 170-2, the fourth insulating layer 190, a gate electrode layer 200-2, a fifth insulating layer 210, a source electrode layer 220-1, a drain electrode layer 220-2, and a sixth insulating layer 230. The third oxide semiconductor layer 170-2 is provided on the third insulating layer 160. The fourth insulating layer 190 is provided on the third insulating layer 160 so as to cover the third oxide semiconductor layer 170-2. The gate electrode layer 200-2 is provided on the fourth insulating layer 190 to overlap the third oxide semiconductor layer 170-2. The fifth insulating layer 210 is provided on the fourth insulating layer 190 to cover the gate electrode layer 200-2. A fourth opening portion OP4 and a fifth opening portion OP5 are provided in the fourth insulating layer 190 and the fifth insulating layer 210. The third oxide semiconductor layer 170-2 is exposed through the fourth opening portion OP4 and the fifth opening portion OP5. The source electrode layer 220-1 is provided inside the fourth opening portion OP4 and on the fifth insulating layer 210. The drain electrode layer 220-2 is provided inside the fifth opening portion OP5 and on the fifth insulating layer 210. The sixth insulating layer 230 is provided on the fifth insulating layer 210 to cover the source electrode layer 220-1 and the drain electrode layer 220-2.

The source electrode layer 220-1 and the drain electrode layer 220-2 are in contact with the third oxide semiconductor layer 170-2 through the fourth opening portion OP4 and the fifth opening portion OP5, respectively. That is, the source electrode layer 220-1 and the drain electrode layer 220-2 are electrically connected to the third oxide semiconductor layer 170-2. A fourth insulating layer 190 is provided between the third oxide semiconductor layer 170-2 and the gate electrode layer 200-2. In the third transistor Tr3, a portion of the fourth insulating layer 190 functions as a gate insulating layer.

The gate electrode layer 200-2 is disposed on the third oxide semiconductor layer 170-2. The third transistor Tr3 is a so-called top-gate transistor. The third transistor Tr3 overlaps the first transistor Tr1. In other words, the third transistor Tr3 is formed over the first transistor Tr1. Therefore, by including the third transistor Tr3 in the semiconductor device 20, the number of transistors can be increased, so that the transistors of the semiconductor device 20 can be highly integrated. In addition, a channel region of the third transistor Tr3 (the region of the third oxide semiconductor layer 170-2 that overlaps the gate electrode layer 200-2) is preferably provided so as to overlap the light shielding layer 110-1. This configuration can prevent external light from entering the channel region of the third oxide semiconductor layer 170-2.

### [1-2. Components of Semiconductor Device 20]

The second transistor Tr2 and the third transistor Tr3 have some of the same components in common. Further, some of the components are formed as the same layer by patterning one deposited film. Hereinafter, the details of each component of the semiconductor device 20 are described, focusing on the second transistor Tr2 and the third transistor Tr3.

### [1-2-1. Second Oxide Semiconductor Layer 170-1 and Third Oxide Semiconductor Layer 170-2]

The second oxide semiconductor layer 170-1 and the third oxide semiconductor layer 170-2 of the second transistor Tr2 are provided as the same layer. That is, the second oxide semiconductor layer 170-1 and the third oxide semiconductor layer 170-2 are simultaneously formed by patterning one oxide semiconductor film. For example, an oxide containing indium, gallium, and zinc (IGZO) can be used for the third oxide semiconductor layer 170-2.

### [1-2-2. Gate Electrode Layer 200-1 and Gate Electrode Layer 200-2]

The gate electrode layer 200-1 of the second transistor Tr2 and the gate electrode layer 200-2 of the third transistor Tr3 are provided as the same layer. That is, the gate electrode layer 200-1 and the gate electrode layer 200-2 are simultaneously formed by patterning one conductive film. The same metal material as the light shielding layer 110-1 can be used for the gate electrode layer 200-1 and the gate electrode layer 200-2.

### [1-2-3. Source Electrode Layer 220-1 and Drain Electrode Layer 220-2]

The source electrode layer 220-1 and the drain electrode layer 220-2 of the third transistor Tr3 are provided as the same layer. That is, the source electrode layer 220-1 and the drain electrode layer 220-2 are simultaneously formed by patterning one conductive film. The same metal material as the light shielding layer 110-1 can be used for the source electrode layer 220-1 and the drain electrode layer 220-2.

### [1-2-4. Sixth Insulating Layer 230]

The sixth insulating layer 230 is a protective layer. An insulating nitride or an insulating oxide similar to the first insulating layer 120 can be used for the sixth insulating layer 230. The sixth insulating layer 230 may have a single layer structure or a stacked structure. For example, the sixth insulating layer 230 may have a stacked structure in which an insulating oxide layer is provided on an insulating nitride layer.

### [2. Manufacturing Method of Semiconductor Device 20]

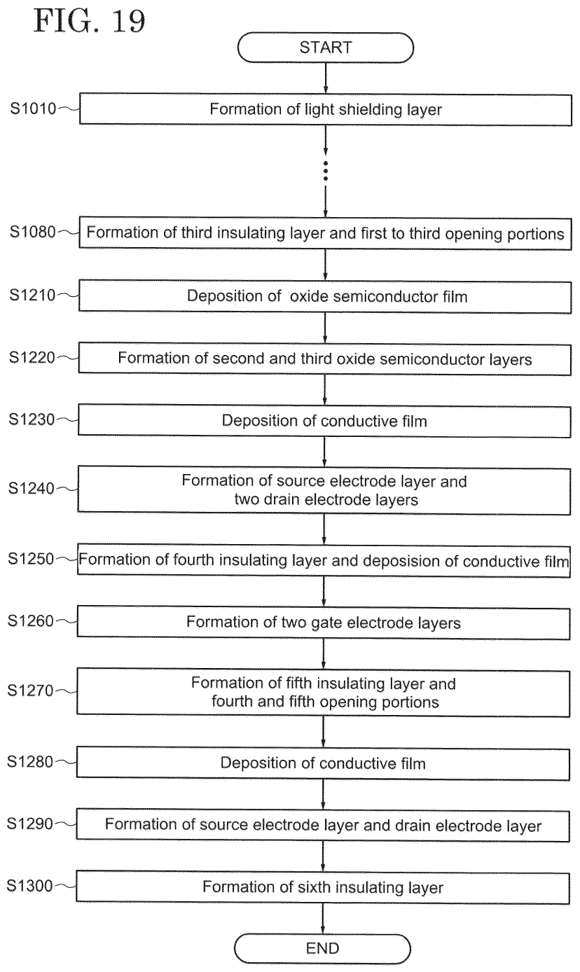

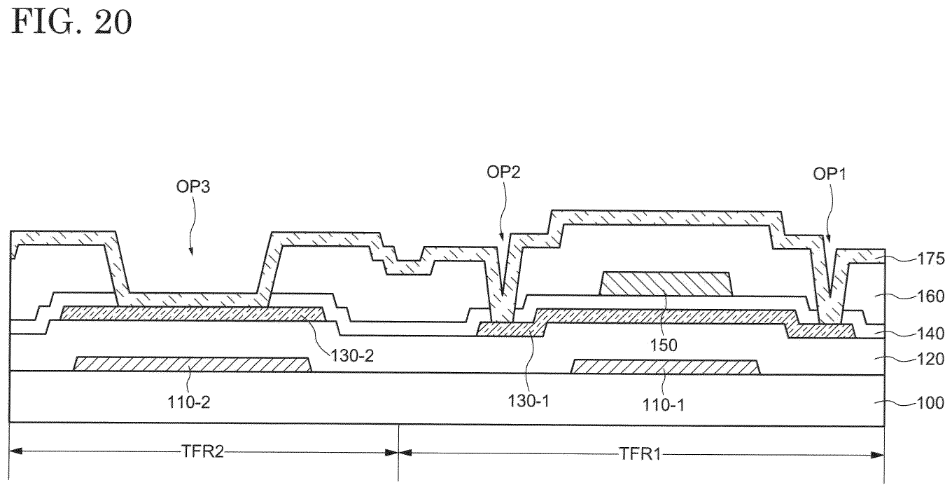

FIG. 19 is a flowchart illustrating a method for manufacturing the semiconductor device 20 according to an embodiment of the present invention. FIGS. 20 to 28 are schematic cross-sectional views illustrating a method for manufacturing the semiconductor device 20 according to an embodiment of the present invention.

Since the method for manufacturing the semiconductor device 20 includes steps S1010 to S1080 in the method for manufacturing the semiconductor device 10, description thereof is omitted here. As shown in FIG. 19, the method for manufacturing the semiconductor device 20 includes steps S1210 to S1300 instead of steps S1090 to S1130. Hereinafter, although steps S1210 to S1300 are described in this order, the order of the steps may be reversed in the method for manufacturing the semiconductor device 20. Further, the method for manufacturing the semiconductor device 20 may also include additional steps. Hereinafter, for convenience of explanation, it is described that the third transistor Tr3 overlaps the first transistor Tr1 and is formed in the first transistor formation region TFR1.

In step S1210, a second oxide semiconductor film 175 is deposited on the third insulating layer 160 so as to cover the bottom surface (i.e., the exposed source electrode layer 130-2) and the side surface of the third opening portion OP3 (see FIG. 20). The second oxide semiconductor film 175 is deposited by a sputtering method.

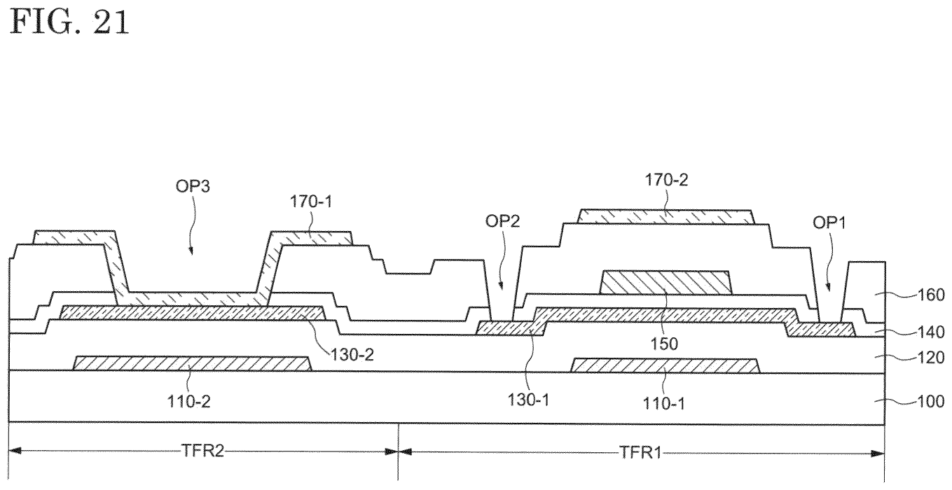

In step S1220, the second oxide semiconductor film 175 is patterned to form the second oxide semiconductor layer 170-1 having a predetermined pattern shape in the second transistor formation region TFR2, and the third oxide semiconductor layer 170-2 having a predetermined pattern shape in the first transistor formation region TFR1 (see FIG. 21). That is, the second oxide semiconductor layer 170-1 and the third oxide semiconductor layer 170-2 are the same layer formed from the second oxide semiconductor film 175. The second oxide semiconductor film 175 is patterned by a photolithography method.

In addition, a heat treatment (so-called OS annealing process) can be performed on the second oxide semiconductor layer 170-1 and the third oxide semiconductor layer 170-2 having a predetermined pattern shape. By the OS annealing process, the second oxide semiconductor layer 170-1 and the third oxide semiconductor layer 170-2 each having a polycrystalline structure can also be formed.

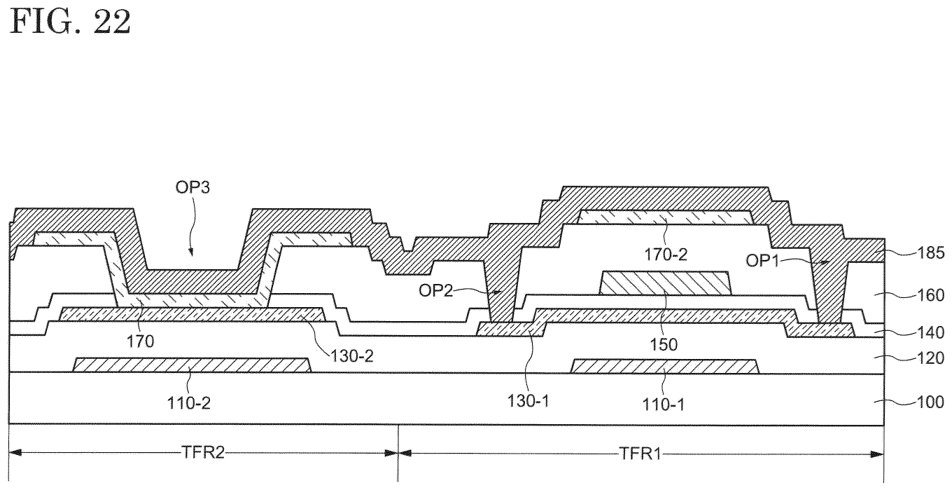

In step S1230, a conductive film 185 is deposited on the third insulating layer 160 so as to cover the second oxide semiconductor layer 170-1 and the third oxide semiconductor layer 170-2 (see FIG. 22). The conductive film 185 is deposited by a sputtering method.

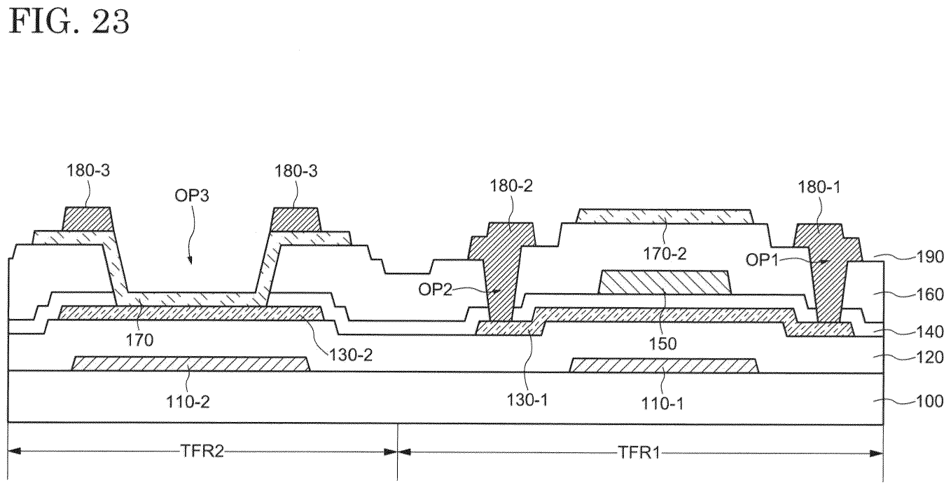

In step S1240, the conductive film 185 is patterned to form the source electrode layer 180-1 and the drain electrode layer 180-2 having a predetermined pattern shape in the first transistor formation region TFR1, and the drain electrode layer 180-3 having a predetermined pattern shape in the second transistor formation region TFR2 (see FIG. 23). That is, the source electrode layer 180-1 and the drain electrode layer 180-2 in the first transistor formation region TFR1 and the drain electrode layer 180-3 in the second transistor formation region TFR2 are the same layer formed from the conductive film 185. The conductive film 185 is patterned by a photolithography method.

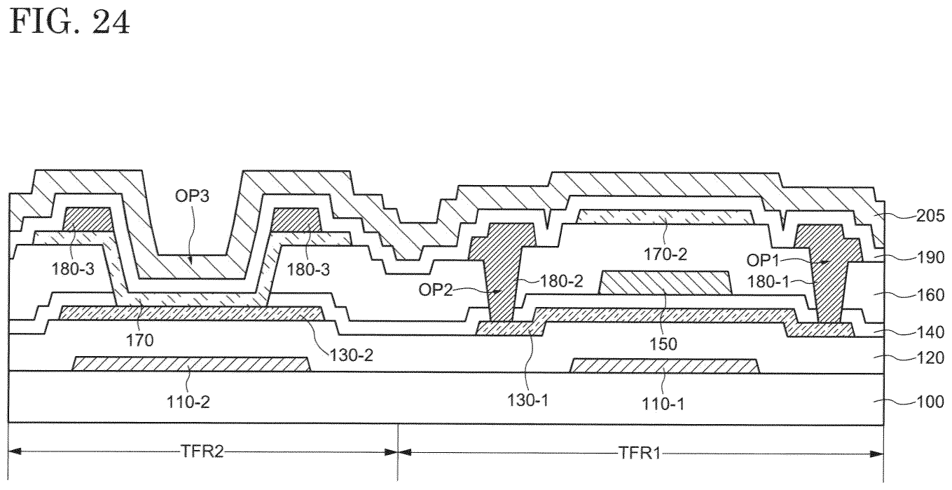

In step S1250, the fourth insulating layer 190 is formed on the third insulating layer 160 so as to cover the source electrode layer 180-1, the drain electrode layer 180-2, and the third oxide semiconductor layer 170-2 in the first transistor formation region TFR1, and the drain electrode layer 180-3 and the third oxide semiconductor layer 170-2 in the second transistor formation region TFR2. Then a conductive film 205 is deposited on the fourth insulating layer 190 (see FIG. 24). The fourth insulating layer 190 is deposited by a CVD method. The conductive film 205 is deposited by a sputtering method.

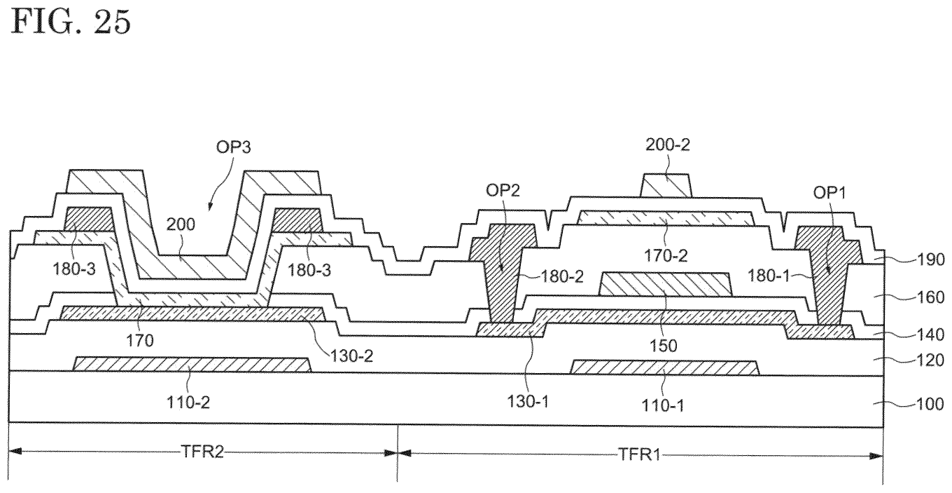

In step S1260, the conductive film 205 is patterned to form the gate electrode layer 200-1 having a predetermined pattern shape in the second transistor formation region TFR2, and the gate electrode layer 200-2 having a predetermined pattern shape in the first transistor formation region TFR1 (see FIG. 25).

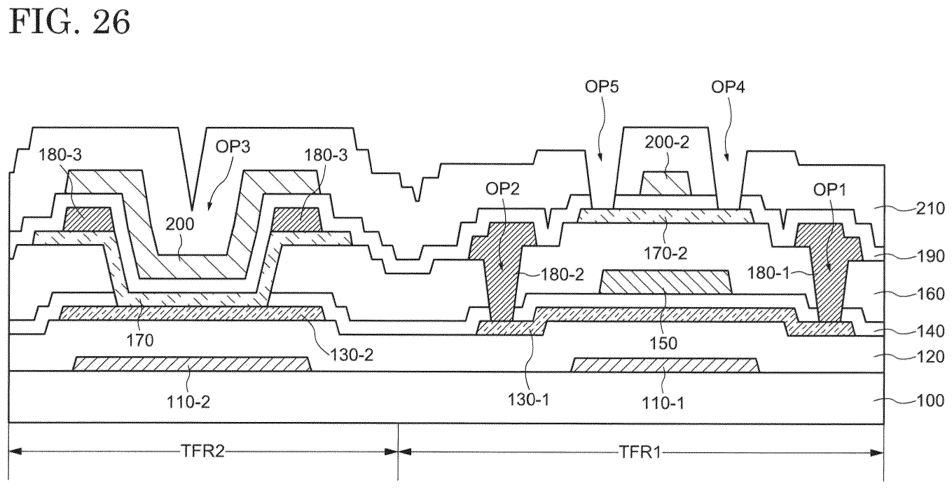

In step S1270, the fifth insulating layer 210 is formed on the fourth insulating layer 190 so as to cover the gate electrode layer 200-1 and the gate electrode layer 200-2, and then a fourth opening portion OP4 and a fifth opening portion OP5 are formed so as to expose the third oxide semiconductor layer 170-2 (see FIG. 26).

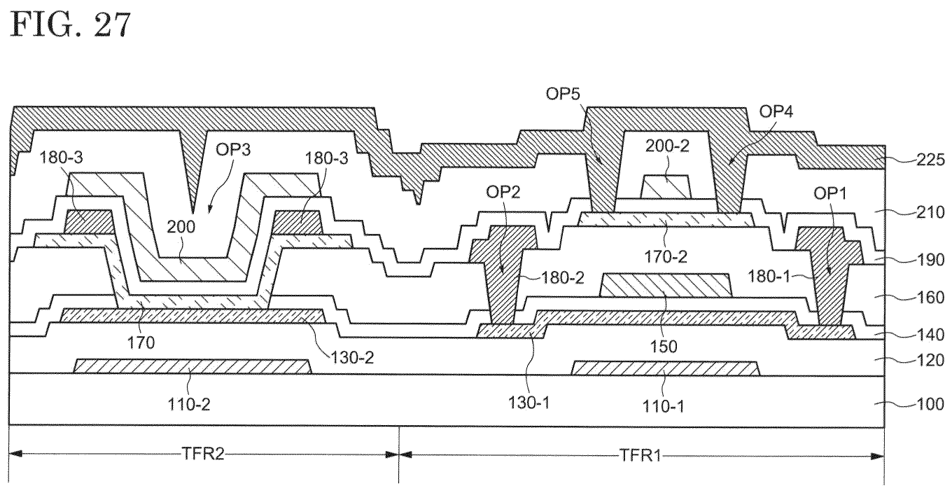

In step S1280, a conductive film 225 is deposited on the fifth insulating layer 210 (see FIG. 27). The conductive film 225 is deposited by a sputtering method.

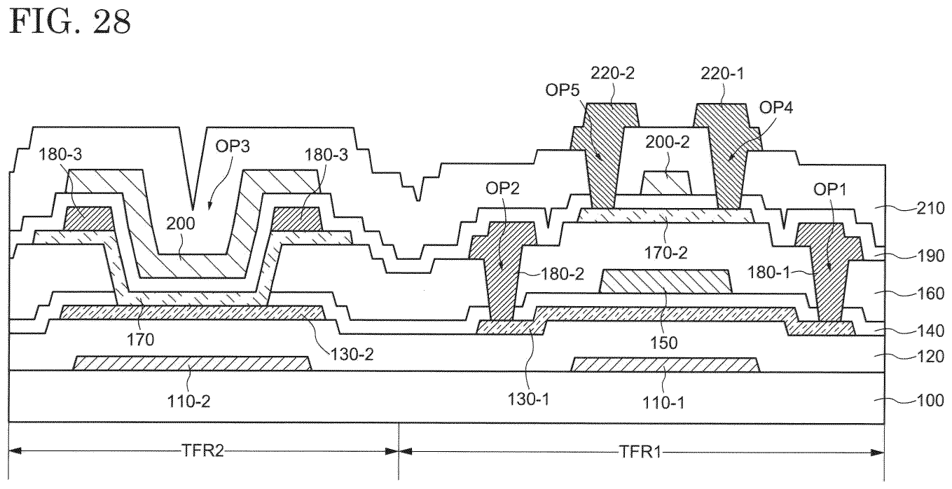

In step S1290, the conductive film 225 is patterned to form the source electrode layer 220-1 and the drain electrode layer 220-2 having a predetermined pattern in the first transistor formation region TFR1 (see FIG. 28). That is, the source electrode layer 220-1 and the drain electrode layer 220-2 are the same layer formed from the conductive film 225. The conductive film 225 is patterned by a photolithography method.

In step S1300, the sixth insulating layer 230 is formed on the fifth insulating layer 210 so as to cover the source electrode layer 220-1 and the drain electrode layer 220-2 having a predetermined pattern shape. In this way, the semiconductor device 20 shown in FIG. 18 is manufactured.

The semiconductor device 20 according to the present embodiment includes the first transistor Tr1 including the first oxide semiconductor layer 130-1, the second transistor Tr2 including the second oxide semiconductor layer 170-1 formed over the first oxide semiconductor layer 130-1, and the third transistor Tr3 including the third oxide semiconductor layer 170-2. The second transistor Tr2 and the third transistor Tr3 have some of their components in common, and the third transistor Tr3 is formed to overlap the first transistor Tr1. The first oxide semiconductor layer 130-1 preferably has thermally stable crystallinity. For example, the first oxide semiconductor layer 130-1 containing the Poly-OS has excellent etching resistance and is less susceptible to thermal load. Therefore, even when the second transistor Tr2 and the third transistor Tr3 are formed after the first oxide semiconductor layer 130-1 of the first transistor Tr1 is formed, the first transistor Tr1 is hardly affected by the formation processes of the second transistor Tr2 and the third transistor Tr3, thereby suppressing fluctuations in the characteristics of the first transistor Tr1. Further, since the second transistor Tr2 is a vertical transistor, the area occupied by the second transistor Tr2 can be reduced. Therefore, high integration of transistors can be achieved in the semiconductor device 20.

### Third Embodiment

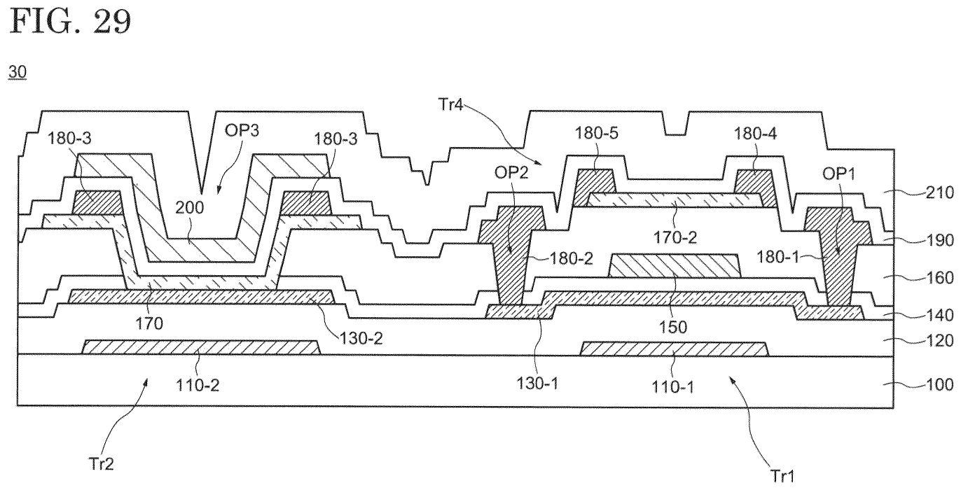

A semiconductor device 30 according to an embodiment of the present invention is described with reference to FIGS. 29 to 32. In addition, when a configuration of the semiconductor device 30 is similar to the configuration of the semiconductor device 10 or the semiconductor device 20, the description of the configuration of the semiconductor device 30 may be omitted.

### [1. Configuration of Semiconductor Device 30]

FIG. 29 is a schematic cross-sectional view showing a configuration of the semiconductor device 30 according to an embodiment of the present invention. As shown in FIG. 29, the semiconductor device 30 includes three transistors (a first transistor Tr1, a second transistor Tr2, and a fourth transistor Tr4) provided on the substrate 100. The structure of the fourth transistor Tr4 is different from the structures of the first to third transistors Tr1 to Tr3.

Here, since a configuration of the first transistor Tr1 according to the present embodiment is similar to the configuration of the first transistor Tr1 described in the First Embodiment, description thereof is omitted. Further, since a configuration of the second transistor Tr2 according to the present embodiment is similar to the configuration of the second transistor Tr2 described in the Second Embodiment, description thereof is omitted.

### [1-1. Configuration of Fourth Transistor Tr4]

The fourth transistor Tr4 includes the second insulating layer 140, the gate electrode layer 150, the third insulating layer 160, a third oxide semiconductor layer 170-2, a source electrode layer 180-4, a drain electrode layer 180-5, the fourth insulating layer 190, and the fifth insulating layer 210. The third insulating layer 160 is provided on the second insulating layer 140 so as to cover the gate electrode layer 150. The third oxide semiconductor layer 170-2 is provided on the third insulating layer 160. Each of the source electrode layer 180-4 and the drain electrode layer 180-5 are provided on the third insulating layer 160 so as to cover a portion of the third oxide semiconductor layer 170-2. The fourth insulating layer 190 is provided on the third insulating layer 160 so as to cover the source electrode layer 180-1, the drain electrode layer 180-2, the drain electrode layer 180-3, the third oxide semiconductor layer 170-2, the source electrode layer 180-4, and the drain electrode layer 180-5.

The source electrode layer 180-4 and the drain electrode layer 180-5 are in contact with the third oxide semiconductor layer 170-2. That is, the source electrode layer 180-4 and the drain electrode layer 180-5 are electrically connected to the third oxide semiconductor layer 170-2. The third insulating layer 160 is provided between the gate electrode layer 150 and the third oxide semiconductor layer 170-2. In the fourth transistor Tr4, a portion of the third insulating layer 160 functions as a gate insulating layer.

The gate electrode layer 150 is disposed below the third oxide semiconductor layer 170-2. Although the fourth transistor Tr4 is a so-called bottom-gate transistor, the gate electrode layer 150 is provided in common with the first transistor Tr1 and the fourth transistor Tr4. Therefore, in the semiconductor device 30, the first transistor Tr1 and the fourth transistor Tr4 operate in conjunction with each other. Further, the fourth transistor Tr4 overlaps the first transistor Tr1. In other words, the fourth transistor Tr4 is formed over the first transistor Tr1. Therefore, by including the fourth transistor Tr4 in the semiconductor device 30, the number of transistors can be increased, so that the transistors of the semiconductor device 30 can be highly integrated.

### [1-2. Components of Semiconductor Device 30]

The second transistor Tr2 and the fourth transistor Tr4 have some of the same components in common. Further, some of the components are formed as the same layer by patterning one deposited film. Hereinafter, details of each component of the semiconductor device 30 are described, focusing on the second transistor Tr2 and the fourth transistor Tr4.

[1-2-1. Source Electrode Layer 180-1, Drain Electrode Layer 180-2, Drain Electrode layer 180-3, Source Electrode Layer 180-4, and Drain Electrode Layer 180-5]

The source electrode layer 180-1 and the drain electrode layer 180-2 of the first transistor Tr1, the drain electrode layer 180-3 of the second transistor Tr2, and the source electrode layer 180-4 and the drain electrode layer 180-5 of the third transistor Tr3 are provided as the same layer. That is, the source electrode layer 180-1, the drain electrode layer 180-2, the drain electrode layer 180-3, the source electrode layer 180-4, and the drain electrode layer 180-5 are simultaneously formed by patterning one conductive film. The same metal material as the light shielding layer 110-1 can be used for the source electrode layer 180-1, the drain electrode layer 180-2, the drain electrode layer 180-3, the source electrode layer 180-4, and the drain electrode layer 180-5.

### [1-2-2. Fourth Insulating Layer 190]

In the fourth transistor Tr4, the fourth insulating layer 190 is a protective layer. However, the fourth insulating layer 190 is in contact with the third oxide semiconductor layer 170-2. Therefore, an insulating oxide can be used for the fourth insulating layer 190. Further, since a portion of the fourth insulating layer 190 functions as a gate insulating layer in the second transistor Tr2, the fourth insulating layer 190 preferably has few defects and a composition close to the stoichiometric ratio. Specifically, it is preferable that no defects are observed in the fourth insulating layer 190 when evaluated by an ESR method.

### [2. Manufacturing Method of Semiconductor Device 30]

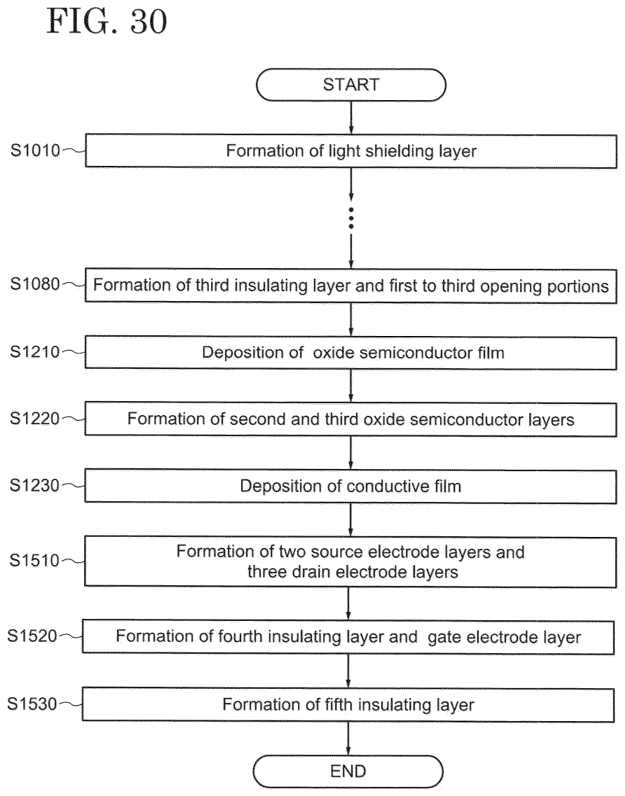

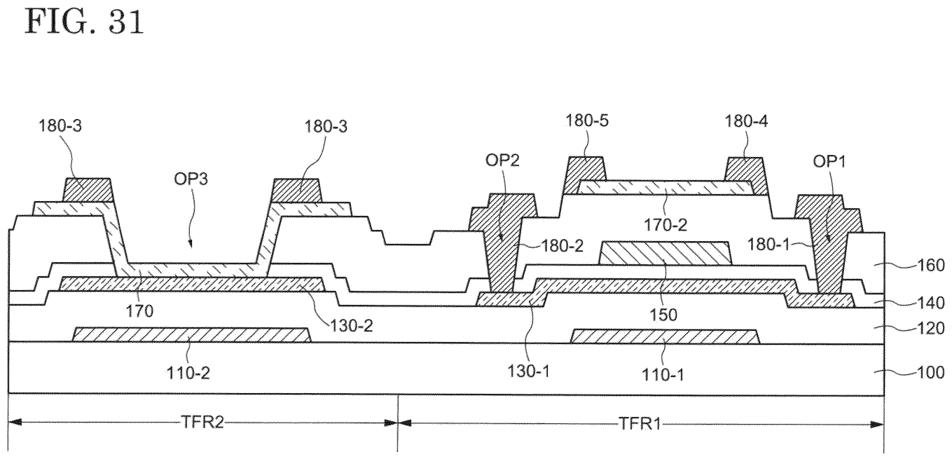

FIG. 30 is a flowchart illustrating a method for manufacturing the semiconductor device 30 according to an embodiment of the present invention. FIG. 31 and. 32 are schematic cross-sectional views illustrating a method for manufacturing the semiconductor device 30 according to an embodiment of the present invention.

Since the method for manufacturing the semiconductor device 30 includes steps S1010 to S1080 and steps S1210 to S1230 in the method for manufacturing the semiconductor device 20, description thereof is omitted here. As shown in FIG. 30, the method for manufacturing the semiconductor device 30 includes steps S1510 to S1530 instead of steps S1240 to S1300. Hereinafter, although steps S1510 to S1530 are described in this order, the order of the steps may be reversed in the method for manufacturing the semiconductor device 30. Further, the method for manufacturing the semiconductor device 30 may include additional steps. Hereinafter, for convenience of explanation, it is described that the fourth transistor Tr4 overlaps the first transistor Tr1 and is formed in the first transistor formation region TFR1.

In step S1510, the conductive film 185 is patterned to form the source electrode layer 180-1, the drain electrode layer 180-2, the source electrode layer 180-4, and the drain electrode layer 180-5 having a predetermined pattern shape in the first transistor formation region TFR1, and the drain electrode layer 180-3 having a predetermined pattern in the second transistor formation region TFR2 (see FIG. 31). That is, the source electrode layer 180-1, the drain electrode layer 180-2, the drain electrode layer 180-3, the source electrode layer 180-4, and the drain electrode layer 180-5 are the same layer formed from the conductive film 185. The conductive film 185 is patterned by a photolithography method.

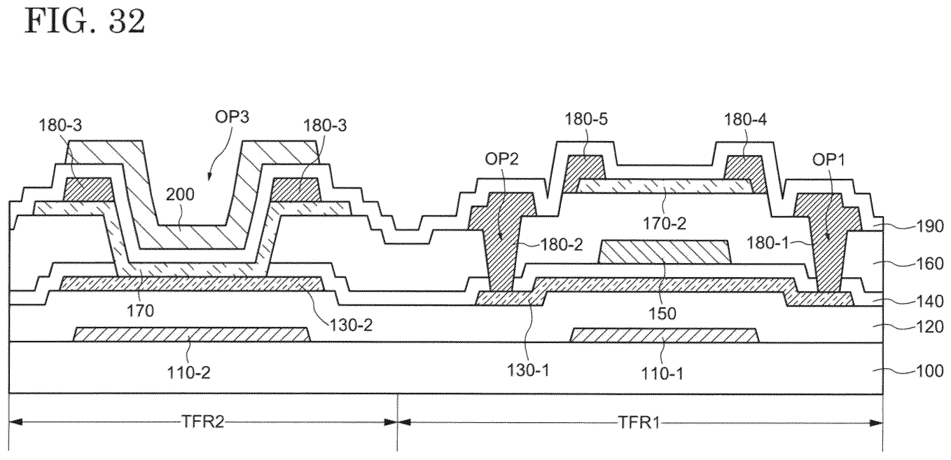

In step S1520, the fourth insulating layer 190 is formed on the third insulating layer 160 so as to cover the source electrode layer 180-1, the drain electrode layer 180-2, the source electrode layer 180-4, the drain electrode layer 180-5, and the third oxide semiconductor layer 170-2 in the first transistor formation region TFR1, as well as the drain electrode layer 180-3 and the second oxide semiconductor layer 170-1 in the second transistor formation region TFR2. Then, in the second transistor formation region TFR2, the gate electrode layer 200 having a predetermined pattern shape is formed on the fourth insulating layer 190 (see FIG. 32). The fourth insulating layer 190 is deposited by a CVD method. The gate electrode layer 200 is deposited using a sputtering method, and the gate electrode layer 200 is patterned by a photolithography method. The gate electrode layer 200 is patterned to have a pattern shape that overlaps the second oxide semiconductor layer 170 on the bottom and side surfaces of the third opening portion OP3 with the fourth insulating layer 190 interposed therebetween.

In step S1530, the fifth insulating layer 210 is formed on the fourth insulating layer 190 so as to cover the gate electrode layer 200 having a predetermined pattern shape. In this way, the semiconductor device 30 shown in FIG. 29 is manufactured.

The semiconductor device 30 according to the present embodiment includes the first transistor Tr1 including the first oxide semiconductor layer 130-1, the second transistor Tr2 including the second oxide semiconductor layer 170-1 and the fourth transistor Tr4 including the third oxide semiconductor layer 170-2 which are formed over the first oxide semiconductor layer 130-1. The second transistor Tr2 and the fourth transistor Tr4 have some of their components in common, and the fourth transistor Tr4 is formed to overlap the first transistor Tr1. The first oxide semiconductor layer 130-1 preferably has thermally stable crystallinity. For example, the first oxide semiconductor layer 130-1 containing Poly-OS has excellent etching resistance and is less susceptible to thermal load. Therefore, even when the second transistor Tr2 and the fourth transistor Tr4 are formed after the first oxide semiconductor layer 130-1 of the first transistor Tr1 is formed, the first transistor Tr1 is hardly affected by the formation processes of the second transistor Tr2 and the fourth transistor Tr4, thereby suppressing fluctuations in the characteristics of the first transistor Tr1. Further, since the second transistor Tr2 is a vertical transistor, the area occupied by the second transistor Tr2 can be reduced. Therefore, high integration of transistors can be achieved in the semiconductor device 30.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device, comprising:
a first transistor comprising a first oxide semiconductor layer; and
a second transistor comprising a second oxide semiconductor layer located over the first semiconductor layer,
wherein the first transistor further comprises:
a first gate electrode layer over the first oxide semiconductor layer, and
an insulating layer over the first gate electrode layer,
wherein the second transistor further comprises:
a source electrode layer, and
a drain electrode layer overlapping the source electrode layer with the second oxide semiconductor layer interposed therebetween,
wherein one of the source electrode layer and the drain electrode layer of the second transistor is provided as a same layer as the first oxide semiconductor layer of the first transistor,
wherein another of the source electrode layer and the drain electrode layer of the second transistor is provided over the insulating layer,
wherein the insulating layer comprises an opening portion in which the one of the source electrode layer and the drain electrode layer is exposed, and
wherein the second oxide semiconductor layer is provided in the opening portion.

2. The semiconductor device according to claim 1, wherein a channel length of the second transistor is less than a channel length of the first transistor.

3. The semiconductor device according to claim 1, wherein the second oxide semiconductor layer comprises a same oxide semiconductor as the first oxide semiconductor layer.

4. The semiconductor device according to claim 1, wherein the second oxide semiconductor layer comprises an oxide semiconductor different from the first oxide semiconductor layer.

5. The semiconductor device according to claim 4, wherein the second oxide semiconductor layer has an amorphous structure.

6. The semiconductor device according to claim 1, further comprising a third transistor comprising a third oxide semiconductor layer located over the first oxide semiconductor layer,
wherein the third oxide semiconductor layer is provided as a same layer as the second oxide semiconductor layer.

7. The semiconductor device according to claim 6, wherein the third transistor further comprises a third gate electrode layer over the third oxide semiconductor layer.

8. The semiconductor device according to claim 6, wherein the third transistor comprises the first gate electrode layer.

9. A semiconductor device, comprising:
a first transistor comprising a first oxide semiconductor layer; and
a second transistor comprising a second oxide semiconductor layer located over the first semiconductor layer,
wherein the first transistor further comprises:
a first gate electrode layer over the first oxide semiconductor layer, and
an insulating layer over the first gate electrode layer,
wherein the second transistor further comprises:
a source electrode layer, and
a drain electrode layer overlapping the source electrode layer with the second oxide semiconductor layer interposed therebetween,
wherein one of the source electrode layer and the drain electrode layer of the second transistor is a portion of the first oxide semiconductor layer of the first transistor,
wherein another of the source electrode layer and the drain electrode layer of the second transistor is provided over the insulating layer, and
wherein the second oxide semiconductor layer is in contact with the first oxide semiconductor layer.

10. The semiconductor device according to claim 9,
wherein the insulating layer comprises an opening portion in which the one of the source electrode layer and the drain electrode layer of the second transistor is exposed, and
wherein the second oxide semiconductor layer is provided in the opening portion.

11. The semiconductor device according to claim 10, wherein the second transistor further comprises a second gate electrode layer overlapping the opening portion over the other of the source electrode layer and the drain electrode layer.

12. The semiconductor device according to claim 9, wherein a channel length of the second transistor is less than a channel length of the first transistor.

13. The semiconductor device according to claim 9, wherein the second oxide semiconductor layer comprises a same oxide semiconductor as the first oxide semiconductor layer.

14. The semiconductor device according to claim 9, wherein the second oxide semiconductor layer comprises an oxide semiconductor different from the first oxide semiconductor layer.

15. The semiconductor device according to claim 14, wherein the second oxide semiconductor layer has an amorphous structure.

16. The semiconductor device according to claim 9, further comprising a third transistor comprising a third oxide semiconductor layer located over the first oxide semiconductor layer,
wherein the third oxide semiconductor layer is provided as a same layer as the second oxide semiconductor layer.

17. The semiconductor device according to claim 16, wherein the third transistor further comprises a third gate electrode layer over the third oxide semiconductor layer.

18. The semiconductor device according to claim 16, wherein the third transistor comprises the first gate electrode layer.
